(19) United States
(12) Patent Application Publication
(10) Pub. No.: US 2022/0141405 A1
(43) Pub. Date: May 5, 2022

(54) DIGITAL PIXEL SENSOR WITH ADAPTIVE NOISE REDUCTION

(71) Applicant: Facebook Technologies, LLC, Menlo Park, CA (US)

(72) Inventors: Tsung-Hsun Tsai, Redmond, WA (US); Xinqiao Liu, Medina, CA (US); Song Chen, Redmond, WA (US); Andrew Samuel Berkovich, Bellevue, WA (US); Lyle David Bainbridge, Redwood City, CA (US)

(21) Appl. No.: 17/517,964

(22) Filed: Nov. 3, 2021

Related U.S. Application Data
(60) Provisional application No. 63/109,661, filed on Nov. 4, 2020.

(51) Int. Cl. H04N 5/357; H04N 5/378

(52) U.S. Cl. CPC H04N 5/3575; H01L 27/14609; H04N 5/378

(57) ABSTRACT

In some examples, a sensor apparatus comprises: a pixel cell configured to generate a voltage, the pixel cell including one or more photodiodes configured to generate a charge in response to light and a charge storage device to convert the charge to a voltage; an integrated circuit comprising a plurality of integrated memory circuits and configured to: generate, based on a first voltage obtained from the charge storage device of the pixel cell, a first voltage value during a first time period; and generate, based on a second voltage generated by fixed pattern noise from the pixel cell and the integrated circuit, a second voltage value occurring a second time period; and one or more analog-to-digital converters (ADC) configured the convert the first voltage value to a first digital pixel value and the second voltage value to a second digital pixel value; and a processor configured to generate a first altered digital pixel value based on the first digital pixel value and the second digital pixel value.

### BACKGROUND

This application claims priority to U.S. provisional patent application Ser. No. 63/109,661, filed Nov. 4, 2020 entitled, “DPS WITH TTS AND SINGLE DIGITAL DOUBLE SAMPLING (DDS) QUANTIZATION,” which is hereby expressly incorporated by reference in its entirety.

### BACKGROUND

A typical image sensor includes an array of pixel cells. Each pixel cell may include a photodiode to sense light by converting photons into charge (e.g., electrons or holes). The image sensor may also include an integrated circuit configured to store the charge generated, amplify the charge and send the amplified charge to an analog-to-digital converter (ADC). The ADC will convert the stored charge into digital values (e.g., “quantize” the charge), as part of processes for digital image generation. Each pixel cell of the array of pixel cells may include an pixel-specific integrated circuit to store and quantize a charge specific to that pixel.

### SUMMARY

The present disclosure relates to image sensors. More specifically, and without limitation, this disclosure relates to a digital image sensor incorporating individual pixel cells including an integrated circuit configured to incorporate a dual quantization circuit with digital double sampling (DDS) for pixel-specific FPN reduction. The image sensor may perform on-sensor processing operations for reducing FPN for each individual pixel cell of an array of pixel cells prior to generation of a digital image to be exported off-sensor.

In some examples, an apparatus is provided. The apparatus includes: 1. A sensor apparatus comprising: a pixel cell configured to generate a voltage, the pixel cell including one or more photodiodes configured to generate a charge in response to light and a charge storage device to convert the charge to a voltage; an integrated circuit comprising a plurality of integrated memory circuits and configured to: generate, based on a first voltage obtained from the charge storage device of the pixel cell, a first voltage value during a first time period; and generate, based on a second voltage generated by fixed pattern noise from the pixel cell and the integrated circuit, a second voltage value occurring a second time period; one or more analog-to-digital converters (ADC) configured the convert the first voltage value to a first digital pixel value and the second voltage value to a second digital pixel value; and a processor configured to generate a third digital pixel value based on the first digital pixel value and the second digital pixel value.

In some aspects, the processor is further configured to determine a threshold pixel value and compare the first digital pixel value to the threshold pixel value, wherein the processor is configured to generate the third digital pixel value based on the comparison. In some further aspects, comparing the first digital pixel value to the threshold pixel value comprises determining that the first digital pixel value is greater or equal to than the threshold pixel value and the third digital pixel value is the first digital pixel value.

In some alternative aspects, comparing the first digital pixel value to the threshold pixel value comprises determining that the first digital pixel value is less than the threshold pixel value and the third digital pixel value is generated based on a difference between the first digital pixel value and the second digital pixel value. In some further aspects, generating the third digital pixel value based on a difference between the first digital pixel value and the second digital pixel value comprising subtracting a binary number representing the second digital pixel value from a binary number representing the first digital pixel value to generate a binary number representing the third digital pixel value.

In some aspects, the threshold pixel value is determined based the first time period and a configuration of the pixel cell. In some aspects, the threshold pixel value is received from an external application executing on a computing device communicatively coupled to the sensor apparatus.

In some aspects, the first digital pixel value is stored on a first static random-access memory of the sensor apparatus, the second digital pixel value is stored on a second static random-access memory of the sensor apparatus, and generating the third digital pixel value comprises accessing, from the first static random-access memory and the second static random-access memory, the first digital pixel value and the second digital pixel value. In some further aspects, the integrated circuit comprises a first memory switch configured to transfer the first voltage value to the first static random-access memory during the first time period, a second memory switch configured to transfer the second voltage value to the first static random-access memory during the first time period, and a latch configured to open and close the first memory switch and the second memory switch during the first and second time periods.

In some aspects, the charge storage device converts the charge from the one or more photodiodes to a voltage during the first time period and does not convert the charge from the one or more photodiodes during the second time period. In some further aspects, the pixel cell comprises a switch to connect the charge storage device to the one or more photodiodes during the first time period and disconnect the charge storage device from the one or more photodiodes after the first time period.

In some aspects, the pixel cell further comprises an adaptive range gate and the pixel cell is configured to generate a charge in a high-gain format when the adaptive range gate is opened and in a moderate-gain format when the adaptive range gate is closed. In some further aspects, the charge storage device is a first charge storage device, the pixel cell further comprises a second charge storage device, the adaptive range gate connecting the one or more photodiodes to the second charge storage device, and the pixel cell is configured to generate a charge in a low-gain format when the adaptive range gate is closed to cause the second charge storage device to convert the charge from the one or more photodiodes to a voltage.

In some aspects, the charge storage device is a first charge storage device, the integrated circuit further comprises a second charge storage device configured to convert a charge from the first charge storage device to a third voltage, and generating the second voltage value is generated based at least on the third voltage converted by the second charge storage device.

In some aspects, the sensor apparatus further comprises a sense amplifier configured to generate an amplified digital pixel value based on the third digital pixel value. In some further aspects, the sensor apparatus further comprises a peripheral processing system comprising the sense amplifier and the processor and the processor is further configured to export the amplified digital pixel value to an external processing system. In some further aspects, the processor is further configured to export the first digital pixel value, the second voltage value, and the third digital pixel value to the external processing system and the external processing system is further configured to generate, based on the first digital pixel value, the first voltage value, the second voltage value, and the third digital pixel value, a fourth digital pixel value.

In some aspects, the peripheral processing system is configured to receive one or more additional digital pixel values from one or more additional processors and generate digital image data using the amplified digital pixel value and the one or more additional digital pixel values. In some further aspects, the peripheral processing system is further configured to export the digital image data to an external application executing on the external processing system and the external processing system comprises a digital display configured to display a digital image generated by the external application based on the digital image data received from the peripheral processing system.

In some examples, a method includes generating a first voltage by converting a charge of light received at one or more photodiodes; generating, using a first memory circuit and based on the first voltage, a first voltage value during a first time period; generating a second voltage based on a fixed pattern noise present in a circuit including the one or more photodiodes; generating, using a second memory circuit and based on the first voltage, a second voltage value occurring a second time period; converting the first voltage value to a first digital pixel value and the second voltage value to a second digital pixel value; and generating an first altered digital pixel value based on the first digital pixel value and the second digital pixel value.

### BRIEF DESCRIPTION OF THE DRAWINGS

Illustrative embodiments are described with reference to the following figures.

FIG. 1 is a block diagram of an embodiment of a system including the near-eye display.

FIG. 2A, FIG. 2B, FIG. 2C, FIG. 2D, FIG. 2E, and FIG. 2F illustrate examples of an image sensor and its operations.

FIG. 3 illustrates example internal components of a pixel cell of a pixel array.

FIG. 4A, FIG. 4B, and FIG. 4C illustrate example components of a peripheral circuit and pixel cell array of an image sensor.

FIG. 5 illustrates an example of a pixel cell and integrated circuit for pixel-specific fixed pattern noise reduction.

FIG. 6 illustrates a timing diagram depicting a time sequence of component activities during a charge capture time period.

FIG. 7 illustrates a digital pixel sensor and flow diagram for receiving light as input and outputting digital data.

FIG. 8 illustrates an example process for pixel specific fixed pattern noise reduction utilizing a noise correction threshold.

The figures depict embodiments of the present disclosure for purposes of illustration only. One skilled in the art will readily recognize from the following description that alternative embodiments of the structures and methods illustrated may be employed without departing from the principles, or benefits touted, of this disclosure.

In the appended figures, similar components and/or features may have the same reference label. Further, various components of the same type may be distinguished by following the reference label by a dash and a second label that distinguishes among the similar components. If only the first reference label is used in the specification, the description is applicable to any one of the similar components having the same first reference label irrespective of the second reference label.

### DETAILED DESCRIPTION

In the following description, for the purposes of explanation, specific details are set forth in order to provide a thorough understanding of certain inventive embodiments. However, it will be apparent that various embodiments may be practiced without these specific details. The figures and description are not intended to be restrictive.

A digital image sensor includes an array of pixel cells. Each pixel cell includes a photodiode to sense incident light by converting photons into charge (e.g., electrons or holes). The charge generated by photodiodes of the array of pixel cells can then be quantized by an analog-to-digital converter (ADC) into digital values. The ADC can quantize the charge by, for example, using a comparator to compare a voltage representing the charge with one or more quantization levels, and a digital value can be generated based on the comparison result. The digital values can then be stored in a memory to generate a digital image.

The digital image data can support various wearable applications, such as object recognition and tracking, location tracking, augmented reality (AR), virtual reality (VR), etc. These and other applications may utilize extraction techniques to extract, from a subset of pixels of the digital image, aspects of the digital image (e.g., light levels, scenery, semantic regions) and/or features of the digital image (e.g., objects and entities represented in the digital image). For example, an application can identify pixels of reflected structured light (e.g., dots), compare a pattern extracted from the pixels with the transmitted structured light, and perform depth computation based on the comparison.

The application can also identify 2D pixel data from the same pixel cells that provide the extracted pattern of structured light to perform fusion of 2D and 3D sensing. To perform object recognition and tracking, an application can also identify pixels of image features of the object, extract the image features from the pixels, and perform the recognition and tracking based on the extraction results. These applications are typically executed on a host processor, which can be electrically connected with the image sensor and receive the pixel data via interconnects. The host processor, the image sensor, and the interconnects can be part of a wearable device.

Digital image sensors are complex apparatuses that convert light into digital image data. The power and precision of a digital image sensor are important factors for how to integrate and implement digital image sensors in various devices and applications. Some applications, such as AR, benefit from a wider range of digital pixel values for display to better represent a real-world environment. High-dynamic-range (HDR) digital image sensors (e.g. image sensors that are capable of generating a wider range of digital pixel values from captured light) are particularly useful in bright or dark environments. HDR digital image sensors utilize particularly sensitive pixel cells for capturing and converting charges to a wider range of digital pixel values to more accurate represent light intensities in an environment.

Powerful digital pixel sensors, such as HDR sensors may also feature pixel-specific integrated circuits for generating more accurate digital pixel values for each pixel of a digital image. For example, an HDR digital image sensor may include an array of individual pixel cells, and each individual pixel cell of the array may include a system-on-chip (SOC circuit) for capturing light-based charges. The individual SOC circuit may be coupled to a corresponding pixel-specific integrated circuit (also referred to as an application-specific integrated circuit, or ASIC) configured to process the charges converted by the SOC circuit for an individual pixel. It is advantageous to make the footprint of each individual pixel cell as small as possible on a digital image sensor in order to more easily integrate the sensor into devices without sacrificing HDR.

Powerful sensors, including HDR digital image sensors, are highly susceptible to fixed pattern noise (FPN). FPN is one or more signals generated by interference and relative differences between components of a digital pixel sensor. For example, fixed pattern noise may be generated when a residual voltage charge that does not originate from light captured at a photodiode is stored in a charge storage device. Accordingly, the charge accumulated in the charge storage device, and a quantized digital pixel value generated from the charge, will not accurately reflect the intensity of the light captured by a photodiode in an individual pixel cell.

FPN may originate from environmental or internal sources. For example, environments from which the digital pixel sensor captures light may also project additional signals besides the light, such as electromagnetic radiation from other sources. This radiation may be captured by a charge storage device and pollute the signal received from the photodiode. Internal sources, such as proximal components, may also generate signals which will further pollute stored charges. For example, as mentioned above, highly compact circuits include a great many components in close proximity. Radiation from components in a pixel cell or integrated circuit may drift from one component to another, changing the accuracy of a measured charge. Residual signal may also remain in a component after the component has been discharged and reset, causing the next stored charge to be skewed before it even begins accumulating.

The highly sensitive components that make up HDR digital pixel sensors often include minute differences among each individual pixel domain (e.g., the pixel cell and associated integrated circuits). For example, the highly sensitive photodiodes in an HDR pixel cell may generate a charge in response to light at a slightly different rate than other photodiodes of other pixel domains. Accordingly, even the same amount of light captured by two different photodiodes may result in two different generated charges. Thus, each individual pixel domain may generate a different fixed pattern noise based on difference in the underlying components.

Methods of reducing fixed pattern noise include utilizing multiple quantization operations by an ADC to determine differences in high-charge density to low-density charges captured. However, quantization operations are time and power consuming operations, which are particularly disadvantageous to limited power devices, such as battery operated electronics. Additionally, because multi-quantization operations are not performed explicitly on a FPN signal, they do not often accurately reflect an appropriate approximation of the FPN captured within a circuit.

Digital double sampling (DDS) utilizes multiple captured of states of a pixel array at different time periods to determine differences between the array states. Based on the differences in states, an external component may attempt to discern the FPN and change pixel values of a digital pixel image prior to display. However, a universal DDS operation is not sufficient to eliminate fixed pattern noise uniformly throughout the entire image. For example, applying a universal DDS mask value to the array of digital pixel values of a digital image may result in appropriate noise corrections of some of the digital pixel values, but may over or under-correct the FPN in other digital pixel values. A static DDS “map” may be generated by an external component and will alter digital pixel values of the digital image at the individual pixel level prior to display. However, this static DDS map will not reflect changing sources of FPN within an environment, especially when the digital image sensor is embedded in a device that may move throughout the environment. Additionally, the application of the mask/map by an external component may require additional power consumption to alter the array of digital pixel value after the array has already been exported off-sensor.

Embodiments described herein relate to a digital pixel sensor implementing on-sensor dual-quantization processes. More specifically, a digital pixel sensor is described implementing an array of individual pixel domains, each domain including a pixel cell and corresponding ASIC. The individual pixel domain captures a signal charge during exposure to light, which is amplified and quantized, and the circuit is then reset. A “reset charge” (or “noise charge”) is then captured and quantized, representing the latent noise in the circuit after the exposure period. A charge threshold may be determined, and a processor may alter the previously quantized signal charge based on the reset charge if the quantized signal charge does not meet the charge threshold.

In some examples, a sensor apparatus comprises a pixel cell configured to generate a voltage, the pixel cell including one or more photodiodes configured to generate a charge in response to light and a charge storage device to convert the charge to a voltage. The pixel cell may be configured as part of a system-on-chip (SOC) pixel and may be one pixel cell in an array of pixel cells. The pixel cell includes its own individual circuit with one or more photodiodes which will generate charge in response to receiving light. The individual pixel cell and corresponding individual circuit may be referred to as a pixel-specific domain, or pixel domain. The amount of charge generated and stored may vary based on the intensity of the incoming light and the amount of time the photodiodes are exposed to the light. A charge storage device, such as a capacitor, will convert the charge generated at the one or more photodiodes into an analog voltage signal that can be used to generate pixel values, as discussed below.

In some examples, the sensor apparatus further comprises an integrated circuit built into an application-specific integrated circuit (ASIC) layer coupled to the SOC pixel. The integrated circuit includes components such as a comparator and a logical state latch to interact with and process the analog voltage signal captured by the charge storage device. For example, the integrated circuit may be configured to generate, based on a first voltage obtained from the charge storage device of the pixel cell, a first voltage value during a first time period and generate, based on a second voltage generated by fixed pattern noise from the pixel cell and the integrated circuit, a second voltage value occurring a second time period. The first voltage value captured during the first time period may be a signal voltage captured and converted at the charge storage device during a time period of exposure for the charge storage device. For example, the first time period may be a time period during which the charge storage device is coupled to a photodiode of an SOC pixel, referred to as an “exposure period.”

The first time period may begin at a time when a switch is engaged to close a circuit between the charge storage device and a photodiode to cause the charge storage device to begin converting a voltage signal. The first time period may end at a time when the switch is later engaged to open the circuit between the charge storage device and the photodiode to prevent further conversion, by the charge storage device, of a voltage signal. Alternatively, the first time period may end at a time when a static random access memory (SRAM) embedded in the ASIC completes storage charge converted by the charge storage device. The first voltage value generated during the first time period may represent a consolidated voltage value generated in the charge storage device during the first time period. This consolidated voltage value contains a charge value converted from the light intake of the photodiode while it is connected to the charge storage device as well as any additional fixed pattern noise generated inherently by the pixel domain and/or its environment. For example, the first voltage value may be generated based on a first voltage obtained from the charge storage device, as well as a fixed-pattern noise signal latent to the pixel-domain.

The second voltage value captured during the second time period may be a reset voltage captured and converted at the charge storage device during a time period following a reset of the pixel domain. For example, the second time period may be a time period during which the charge storage device is not coupled to a photodiode, but may be generating a voltage signal-based charge due to latent fixed-pattern noise captured by the charge storage device and/or other components of the pixel domain. For example, the second voltage value may be a voltage value generated by the charge storage device and a comparator following a reset pulse of the ASIC. Thus, the second voltage value may be generated based on a second voltage naturally generated by the pixel-domain without the conversion of the charges from the photodiode that occur during the first time period.

The second time period may begin at a time subsequent to the first time period and following a reset pulse of the circuits within the pixel domain. The reset of the circuits within the pixel domain may be initiated to purge the pixel domain of any previously captured signals during the first time period and to prepare the pixel domain for another subsequent exposure period. During this second time period, the charge storage device will not be connected to the photodiode and thus will not accumulate and convert charges from light captured by the photodiode. Thus, charges captured during the second time period will represent latent voltages within the pixel domain while the exposure period is not occurring. These latent voltages are associated with fixed-pattern noise inherent to the environment and pixel-specific domain at which they are measured. The second time period may conclude shortly thereafter, once the latent voltage signals have been appropriately stored by a SRAM.

In some examples, the sensor apparatus further comprises one or more analog-to-digital converters (ADC) configured to convert captured voltages to digital pixel data comprising one or more digital pixel values. Specifically, the ADC may convert an analog voltage signal stored at the charge storage device into digital data including a digital pixel value representing the captured intensity of incoming light at the pixel cell (referred to as “quantizing” the analog voltage signal). For example, the ADC(s) may convert the first voltage value to a first digital pixel value and the second voltage value to a second digital pixel value. In some embodiments, the first voltage value and the second voltage value may be converted differently by the ADC(s) depending on the time period during which the voltage value is received (and therefore the SRAM to which the voltage signal is sent). For example, a first charge (signal charge) may be sent to a first SRAM and converted to a 9-bit digital value during a first time period of capture, which is sufficient to represent the intensity of the light and FPN captured during the exposure period. The second voltage value may be converted differently to reduce power consumption while accurately representing the intensity of the FPN captured. For example, a second charge (reset charge) may be sent to a second SRAM during a second time period and converted to a 6-bit digital value, which is sufficient to represent the intensity of the FPN captured during the exposure period. It will be appreciated that the first and second SRAM be different sizes different sizes, contain different components, be made of different materials, etc., based on the different conversion configurations of the first and second SRAM.

In some examples, the sensor apparatus further comprises one or more processors configured to alter the digital pixel values converted by the ADC and/or generate a new digital pixel value. For example, the processor may be configured to generate a third digital pixel value based on the first digital pixel value and the second digital pixel value quantized by the ADC. Generation of an third digital pixel value will allow the sensor to more accurately represent light captured by pixel cells of the array of pixel cells and processed at a corresponding ASIC by reducing FPN from the first digital pixel value prior to off-sensor export. For example, the second digital pixel value, which may have been converted to a 6-bit number value from the latent voltage signal generated in a particular pixel domain, may be subtracted from the first digital pixel value, which may have been converted to a 9-bit number value based on the voltage signal generated in the particular pixel domain during the exposure period. The resulting third digital pixel value (representing the difference between the first and second digital pixel values) may approximate the charge captured by the photodiode absent the FPN inherently generated by the particular pixel domain.

In some examples, the charge storage device converts the charge from the one or more photodiodes to a voltage during the first time period and does not convert the charge from the one or more photodiodes during the second time period. For example, the pixel cell may include a switch to connect the charge storage device to the one or more photodiodes during the first time period and disconnect the charge storage device from the one or more photodiodes during the second time period. The switch may separate the charge storage device from the photodiode and be a part of the SOC pixel, or may be a switch on the periphery of the SOC pixel to connect the SOC pixel to the corresponding integrated circuit for processing the captured and stored charges.

In some cases, the FPN generated by a pixel domain is relatively small compared to the total signal charge generated during the exposure period. For example, in high intensity (e.g., very bright) lights, the sensor and corresponding pixel domains that capture the light may generate charge values that are significantly larger than the FPN generated inherently by the pixel domains. Generating the altered digital pixel value from the first and second digital pixel values consumes energy while the processor of the sensor performed the alteration and any associated calculations. In some instances, removal of fixed pattern noise from the first digital pixel value may only improve the digital image generated by the digital image sensor marginally. This marginally beneficial operation still consumes energy, and the detriment of the loss of energy outweighs the benefit of the removal of the fixed pattern noise.

In some examples, the integrated circuit is further configured to determine a threshold pixel value, the threshold pixel value being a threshold value corresponding to the first digital pixel value quantized by an ADC. Any digital pixel values that are greater than (or in some cases equal to) the threshold pixel value may not be subjected to an alteration operation prior to export of the digital pixel value off-sensor. That is because the relatively-high intensity of the captured charge “drowns out” the fixed pattern noise when the light captured is highly intense (e.g., a very bright light). Accordingly, any digital pixel value that is less than (or in some cases equal to) the threshold pixel value may be subject to the alteration operation prior to export of the digital pixel value off-sensor. That is because the relatively-low intensity of the charge is “polluted” with the fixed pattern noise when the signal charge is closer in intensity to the FPN. In essence, the lower the intensity of a captured signal charge is, the higher the proportion of the charge that made up of the fixed pattern noise. This may be determined by a comparison of the converted first digital pixel value and the threshold pixel value.

In some examples, the threshold pixel value is determined based the first time period and a configuration of the pixel cell. For example, the threshold pixel value for alteration may be based on the period of time during which the charge storage device will convert charges (e.g. the exposure period) and the type of configuration of the pixel cell, and may be established by comparing a stored voltage against a threshold voltage. For example, longer exposure periods and more sensitive photodiodes often result in higher voltage signals captured at a pixel cell. The threshold pixel value may be determined and/or modified based on these factors by the digital image sensor or an external application that communicates with the digital image sensor. In some embodiments, the threshold pixel value is set based on a level of FPN detected in one or more pixel domains. For example, the threshold pixel value may be set proportionally to a mean, median, or modal value of FPN quantized in previous frame captures of a digital pixel sensor. In some examples, the threshold pixel value is determined based on data received from an external application executing on a computing device communicatively coupled to the sensor apparatus. For example, the digital pixel sensor described herein may be coupled to a VR or AR display device to utilize digital images generated by the digital pixel sensor to display, to a user, an environment captured by the digital pixel sensor. The environment may require more or less accuracy of generated digital images based on the application running (e.g., AR application may generate lower resolution artifact due to the “pass-through” nature of the display, while VR applications may require higher resolution images to improve environmental “immersion.” Because of the nature of the application, the threshold may be set accordingly to preserve power or reduce resource-intensive communications.

In some examples, generating the first altered digital pixel value includes determining a difference value based on the first digital pixel value and the second digital pixel value; and altering the first digital pixel value based on the difference value. This may include subtracting the second digital pixel value representing the quantized fixed pattern noise of a pixel domain from the total signal charge of the first digital pixel value. The resulting difference will then represent the signal captured from light by the photodiode without the FPN generated by the pixel domain.

As discussed above, in some examples, the first digital pixel value is stored on a first static random-access memory of the sensor apparatus, the second digital pixel value is stored on a second static random-access memory of the sensor apparatus, and generating the third digital pixel value comprises accessing, from the first static random-access memory and the second static random-access memory, the first digital pixel value and the second digital pixel value. For example a first SRAM used to store the first digital pixel value and a second SRAM used to store the second digital pixel value may send both values to an on-sensor processor to perform calculations related to FPN reduction. In some examples, both the first and second SRAM are coupled to the rest of the ASIC via switches configured to transfer the respective voltage values generated by the pixel domain to the SRAMs at the corresponding time period. A latch in the ASIC may be configured to open and close the switches at these time periods to convert the voltages to digital pixel values.

In some examples, instead of utilizing switches to connect the SRAMs to the rest of the ASIC, the integrated circuit may utilize an ADC digital counter to track the time periods of exposure and reset and send signals to the SRAMs during each period respectively. For example, the integrated circuit may be further configure to receive, during the first and second time periods, a series of ADC count signals indicating the current time period of a frame capture by the digital pixel sensor. Thus, generating the first voltage value and the second is based on the series of ADC count signals and does not require the use of physical component switches when sending the first and second voltage signals to the corresponding first and second SRAM.

In some examples, an adaptive range gate and additional charge storage device may be integrated into the pixel cell to increase the dynamic range of light intensities that may be converted by the pixel-domain. For example, an adaptive range gate and/or an additional capacitor connected to the photodiode via the adaptive range gate may allow the pixel cell to generate high, moderate or low-gains of light intensity capture, or any range in between. In some examples, the ASIC may include an additional charge storage device between the pixel cell and the ASIC. The additional pixel cell may be configured to allow the pixel domain to perform DDS operations with regards to either the first voltage value and/or the second voltage value. For example, an additional capacity may be included between the pixel cell and the ASIC to improve voltage sampling accuracy when generating the first and second voltages.

In some examples, a sense amplifier may be included in a periphery processing system of the digital pixel sensor. The sense amplifier may be configured to amplify the signal of a quantized digital pixel value prior to export of the digital pixel value off-sensor.

In some examples, the processor is further configured to export the first altered digital pixel value to an peripheral processing system. The peripheral processing system may be an on-sensor processing system configured to generate a digital image to be used as part of an off-sensor application or process. For example, the periphery of the digital pixel sensor may receive, from each pixel domain of the digital image sensor, a number of digital pixel values which will be utilized to compile an array of digital pixel values to make a digital image. The digital image may be exported to an off-sensor display module configured to display the digital image using the array of altered digital pixel values.

In some examples, the processor is further configured to export the first voltage value and the second voltage value to an external processing system configured to generate, based on the third digital pixel value, the first voltage value, and the second voltage value, a fourth digital pixel value. The external processing system may further alter the third digital pixel value as part of a supplementary noise-reducing operation that occurs off-sensor to generate a new fourth digital pixel value. For example, in additional to the alternation to remove FPN performed by the on-sensor processor, a second off-sensor processor may further alter the digital pixel values of the digital image for display and interaction as part of an application, such as an AR or VR application. The digital images generated in this matter may be utilized by an external processing system, for example a digital display system incorporating an application, to display an image including, as a portion, the third digital pixel value generated by an pixel-domain. The digital image may thus be made up of many digital pixel values generated by many pixel-domains during a frame capture.

In some examples, a method includes the processes described above with respect to the application system and the sensor apparatus. The disclosed techniques may include or be implemented in conjunction with an artificial reality system. Artificial reality is a form of reality that has been adjusted in some manner before presentation to a user, which may include, for example, a virtual reality (VR), an augmented reality (AR), a mixed reality (MR), a hybrid reality, or some combination and/or derivatives thereof. Artificial reality content may include completely generated content or generated content combined with captured (e.g., real-world) content. The artificial reality content may include video, audio, haptic feedback, or some combination thereof, any of which may be presented in a single channel or in multiple channels (such as stereo video that produces a three-dimensional effect to the viewer). Additionally, in some embodiments, artificial reality may also be associated with applications, products, accessories, services, or some combination thereof, that are used to, for example, create content in an artificial reality and/or are otherwise used in (e.g., perform activities in) an artificial reality. The artificial reality system that provides the artificial reality content may be implemented on various platforms, including a head-mounted display (HMD) connected to a host computer system, a standalone HMD, a mobile device or computing system, or any other hardware platform capable of providing artificial reality content to one or more viewers.

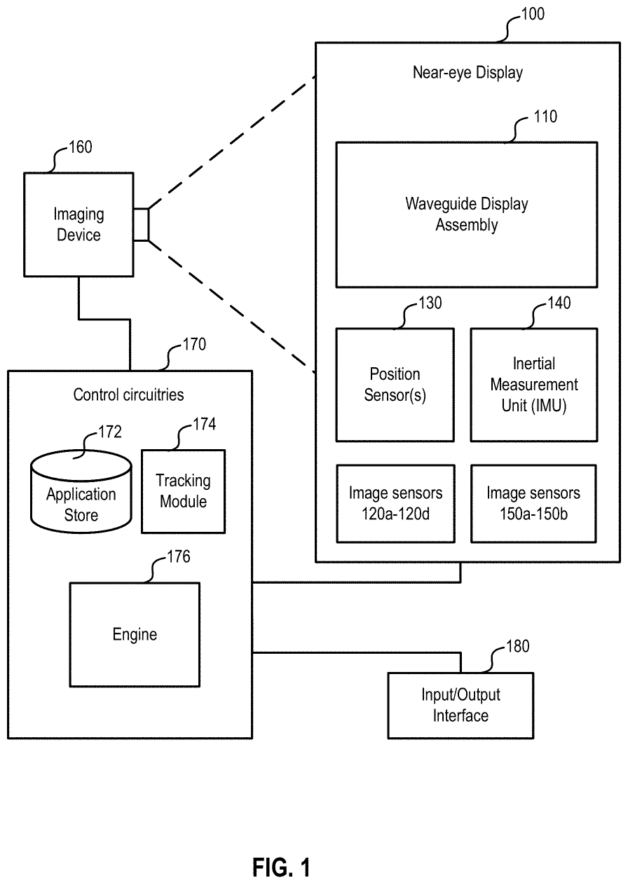

FIG. 1 is a block diagram of an embodiment of a system including the near-eye display 100. The system includes near-eye display 100, an imaging device 160, an input/output interface 180, and image sensors 120a-120d and 150a-150b that are each coupled to control circuitries 170. System 100 can be configured as a head-mounted device, a wearable device, etc.

Near-eye display 100 is a display that presents media to a user. Examples of media presented by the near-eye display 100 include one or more images, video, and/or audio. In some embodiments, audio is presented via an external device (e.g., speakers and/or headphones) that receives audio information from near-eye display 100 and/or control circuitries 170 and presents audio data based on the audio information to a user. In some embodiments, near-eye display 100 may also act as an AR eyewear glass. In some embodiments, near-eye display 100 augments views of a physical, real-world environment, with computer-generated elements (e.g., images, video, sound).

Near-eye display 100 includes waveguide display assembly 110, one or more position sensors 130, and/or an inertial measurement unit (IMU) 140. Waveguide display assembly 110 may include a source assembly, output waveguide, and controller.

IMU 140 is an electronic device that generates fast calibration data indicating an estimated position of near-eye display 100 relative to an initial position of near-eye display 100 based on measurement signals received from one or more of position sensors 130.

Imaging device 160 may generate image data for various applications. For example, imaging device 160 may generate image data to provide slow calibration data in accordance with calibration parameters received from control circuitries 170. Imaging device 160 may include, for example, image sensors 120a-120d for generating image data of a physical environment in which the user is located, for performing location tracking of the user. Imaging device 160 may further include, for example, image sensors 150a-150b for generating image data for determining a gaze point of the user, to identify an object of interest of the user.

The input/output interface 180 is a device that allows a user to send action requests to the control circuitries 170. An action request is a request to perform a particular action. For example, an action request may be to start or end an application or to perform a particular action within the application.

Control circuitries 170 provide media to near-eye display 100 for presentation to the user in accordance with information received from one or more of: imaging device 160, near-eye display 100, and input/output interface 180. In some examples, control circuitries 170 can be housed within system 100 configured as a head-mounted device. In some examples, control circuitries 170 can be a standalone console device communicatively coupled with other components of system 100. In the example shown in FIG. 1, control circuitries 170 include an application store 172, a tracking module 174, and an engine 176.

The application store 172 stores one or more applications for execution by the control circuitries 170. An application is a group of instructions, that, when executed by a processor, generates content for presentation to the user. Examples of applications include: gaming applications, conferencing applications, video playback applications, or other suitable applications.

Tracking module 174 calibrates system 100 using one or more calibration parameters and may adjust one or more calibration parameters to reduce error in determination of the position of the near-eye display 100.

Tracking module 174 tracks movements of near-eye display 100 using slow calibration information from the imaging device 160. Tracking module 174 also determines positions of a reference point of near-eye display 100 using position information from the fast calibration information.

Engine 176 executes applications within system 100 and receives position information, acceleration information, velocity information, and/or predicted future positions of near-eye display 100 from tracking module 174. In some embodiments, information received by engine 176 may be used for producing a signal (e.g., display instructions) to waveguide display assembly 110 that determines a type of content presented to the user. For example, to provide an interactive experience, engine 176 may determine the content to be presented to the user based on a location of the user (e.g., provided by tracking module 174), or a gaze point of the user (e.g., based on image data provided by imaging device 160), a distance between an object and user (e.g., based on image data provided by imaging device 160).

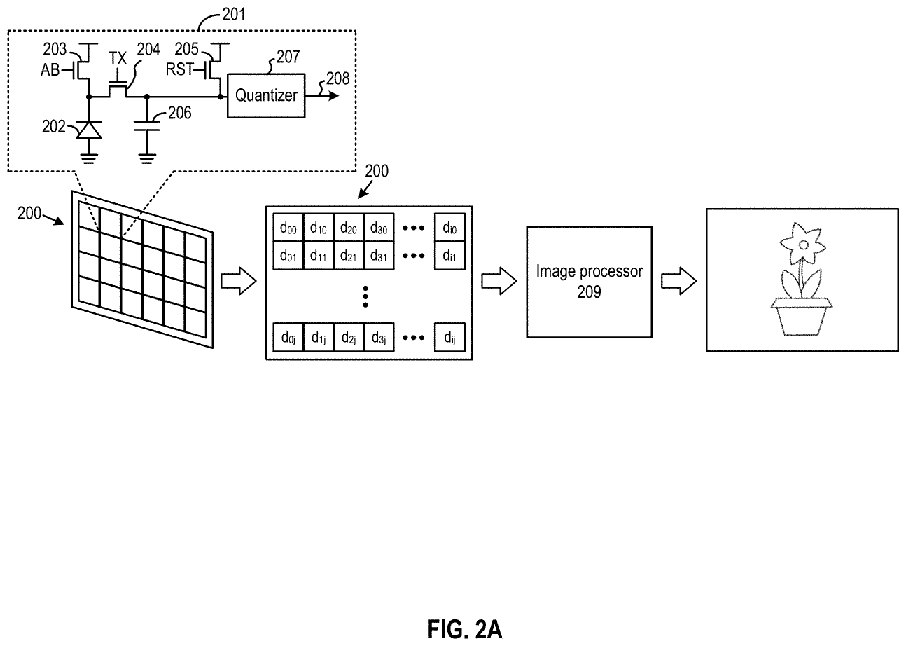

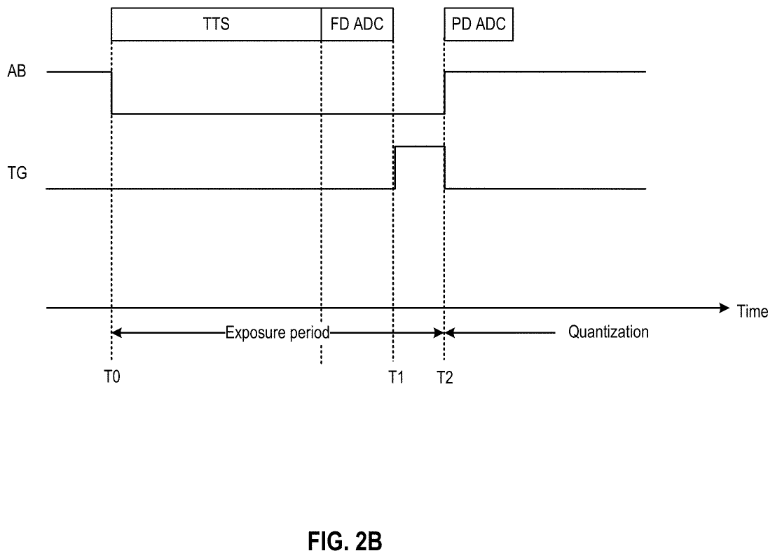

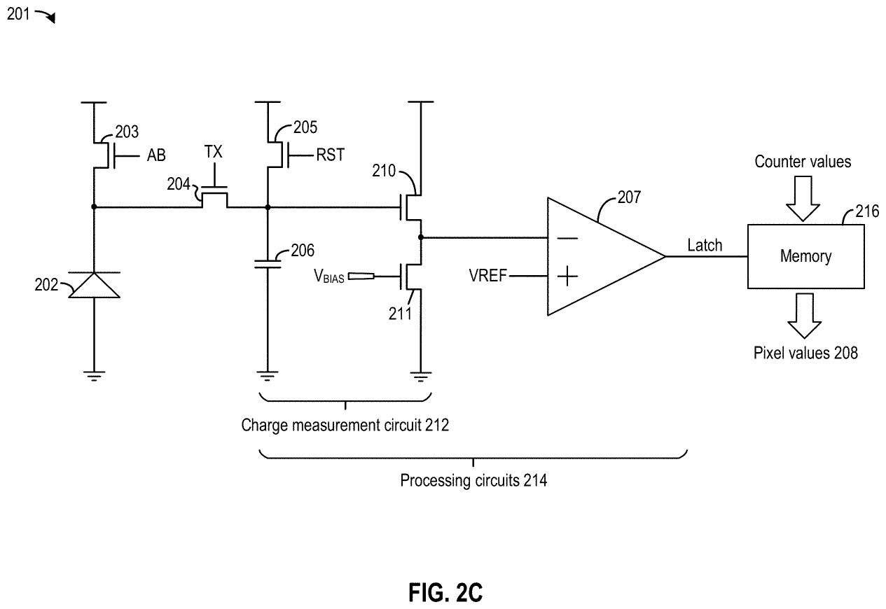

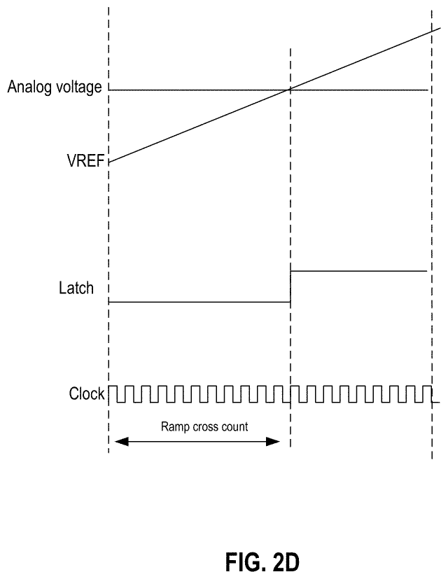

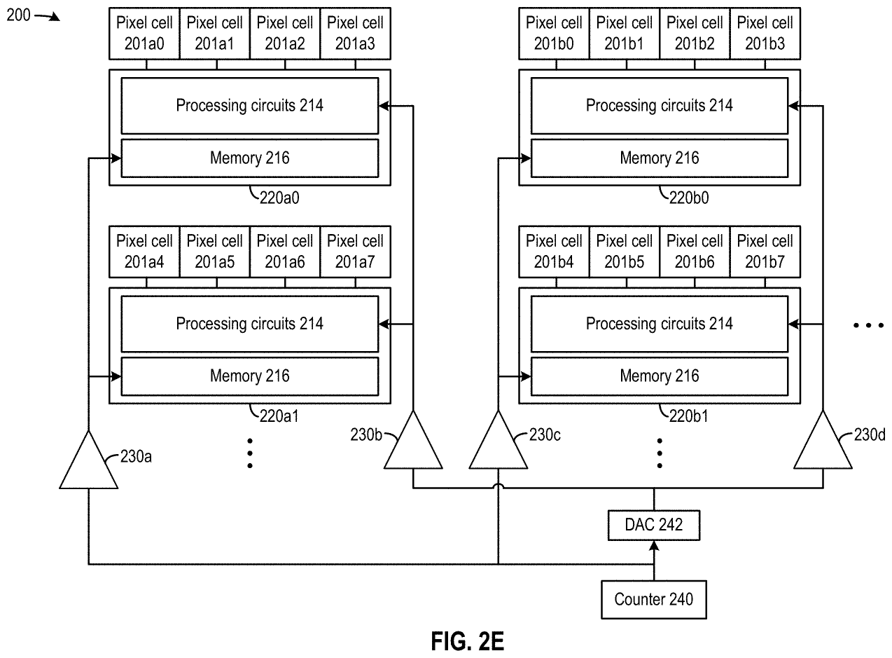

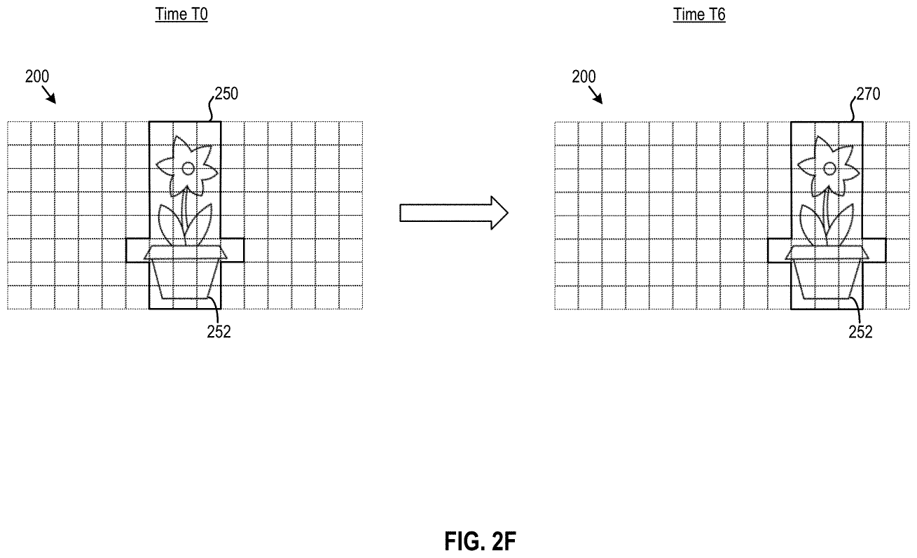

FIG. 2A, FIG. 2B, FIG. 2C, FIG. 2D, FIG. 2E, and FIG. 2F illustrate examples of an image sensor 200 (e.g., a digital image sensor) and its operations. As shown in FIG. 2A, image sensor 200 can include an array of pixel cells, including pixel cell 201, and can generate digital intensity data corresponding to pixels of an image. Pixel cell 201 may be part of an array of pixel cells in an image sensor 200. As shown in FIG. 2A, pixel cell 201 may include one or more photodiodes 202, an electronic shutter switch 203, a transfer switch 204, a reset switch 205, a charge storage device 206, and a quantizer 207. Quantizer 207 can be a pixel-level ADC that is accessible only by pixel cell 201. Photodiode 202 may include, for example, a P-N diode, a P-I-N diode, or a pinned diode, whereas charge storage device 206 can be a floating diffusion node of transfer switch 204. Photodiode 202 can generate and accumulate charge upon receiving light within an exposure period, and the quantity of charge generated within the exposure period can be proportional to the intensity of the light.

The exposure period can be defined based on the timing of AB signal controlling electronic shutter switch 203, which can steer the charge generated by photodiode 202 away when enabled, and based on the timing of the TX signal controlling transfer switch 204, which can transfer the charge generated by photodiode 202 to charge storage device 206 when enabled. For example, referring to FIG. 2B, the AB signal can be de-asserted at time T0 to allow photodiode 202 to generate charge and accumulate at least some of the charge as residual charge until photodiode 202 saturates. T0 can mark the start of the exposure period. The TX signal can set transfer switch 204 at a partially-on state to transfer additional charge (e.g., overflow charge) generated by photodiode 202 after saturation to charge storage device 206. At time T1, the TG signal can be asserted to transfer the residual charge to charge storage device 206, so that charge storage device 206 can store all of the charge generated by photodiode 202 since the beginning of the exposure period at time T0.

At the time T2, the TX signal can be de-asserted to isolate charge storage device 206 from photodiode 202, whereas the AB signal can be asserted to steer charge generated by photodiode 202 away. The time T2 can mark the end of the exposure period. An analog voltage across charge storage device 206 at time T2 can represent the total quantity of charge stored in charge storage device 206, which can correspond to the total quantity of charge generated by photodiode 202 within the exposure period. Both TX and AB signals can be generated by a controller (not shown in FIG. 2A) which can be part of pixel cell 201. After the analog voltage is quantized, reset switch 205 can be enabled by an RST signal to remove the charge in charge storage device 206 to prepare for the next measurement.

FIG. 2C illustrates additional components of pixel cell 201. As shown in FIG. 2C, pixel cell 201 can include a source follower 210 that can buffer the voltage at charge storage device 206, and output the voltage to quantizer 207. Charge storage device 206 and source follower 210 can form a charge measurement circuit 212. Source follower 210 can include a current source 211 controlled by a bias voltage V_{BIAS}, which sets the current that flows through source follower 210. Quantizer 207 can include a comparator. Charge measurement circuit 212 and quantizer 207 together can form a processing circuits 214. The comparator is further coupled with a memory 216 to store a quantization output as pixel value 208. Memory 216 can include a bank of memory devices, such as static random-access memory (SRAM) devices, with each memory device configured as a bit cell. The number of memory devices in the bank can be based on a resolution of the quantization output. For example, if the quantization output has a 10-bit resolution, memory 216 can include a bank of ten SRAM bit cells. In a case where pixel cell 201 includes multiple photodiodes to detect light of different wavelength channels, memory 216 may include multiple banks of SRAM bit cells.

Quantizer 207 can be controlled by the controller to quantize the analog voltage after time T2 to generate a pixel value 208. FIG. 2D illustrates an example quantization operation performed by quantizer 207. As shown in FIG. 2D, quantizer 207 can compare the analog voltage output by source follower 210 with a ramping reference voltage (labelled “VREF” in FIG. 2C and FIG. 2D) to generate a comparison decision (labelled “Latch” in FIG. 2C and FIG. 2D). The time it takes for the decision to trip can be measured by a counter to represent a result of quantization of the analog voltage. In some examples, the time can be measured by a free-running counter that starts counting when the ramping reference voltage is at the start point. The free-running counter can periodically updates its count value based on a clock signal (labelled “clock” in FIG. 2D) and as the ramping reference voltage ramps up (or down). The comparator output trips when the ramping reference voltage meets the analog voltage. The tripping of the comparator output can cause a count value to be stored in memory 216. The count value can represent a quantization output of the analog voltage. Referring back to FIG. 2C, the count value stored in memory 216 can be read out as pixel value 208.

In FIG. 2A and FIG. 2C, pixel cell 201 is illustrated as including processing circuits 214 (including charge measurement circuit 212 and quantizer 207) and memory 216. In some examples, processing circuits 214 and memory 216 can be external to pixel cell 201. For example, a block of pixel cells can share and take turn in accessing processing circuits 214 and memory 216 to quantize the charge generated by the photodiode(s) of each pixel cell and to store the quantization result.

FIG. 2E illustrates additional components of image sensor 200. As shown in FIG. 2E, image sensor 200 includes pixel cells 201 arranged in rows and columns, such as pixel cells 201a0-a3, 201a4-a7, 201b0-b3, or 201b4-b7. Each pixel cell may include one or more photodiodes 202. Image sensor 200 further includes quantization circuits 220 (e.g., quantization circuit 220a0, a1, b0, b1) comprising processing circuits 214 (e.g., charge measurement circuit 212 and comparator/quantizer 207) and memory 216. In the example of FIG. 2E, a block of four pixel cells may share a block-level quantization circuit 220, which can include a block-level ADC (e.g., comparator/quantizer 207) and a block-level memory 216 via a multiplexor (not shown in FIG. 2E), where each pixel cell takes turn in accessing quantization circuit 220 to quantize the charge. For example, pixel cells 201a0-a3 share quantization circuit 220a0, pixel cells 201a4-a7 share quantization circuit 221a1, pixel cells 201b0-b3 share quantization circuit 220b0, whereas pixel cells 201b4-b7 share quantization circuit 220b1. In some examples, each pixel cell may include or has its dedicated quantization circuit.

In addition, image sensor 200 further includes other circuits, such as a counter 240 and a digital-to-analog converter (DAC) 242. Counter 240 can be configured as a digital ramp circuit to supply count values to memory 216. The count values can also be supplied to DAC 242 to generate an analog ramp, such as VREF of FIG. 2C and FIG. 2D, which can be supplied to quantizer 207 to perform the quantization operation. Image sensor 200 further includes a buffer network 230 including buffers 230a, 230b, 230c, 230d, etc. to distribute the digital ramp signals representing the counter values, and the analog ramp signal, to processing circuits 214 of different blocks of pixel cells, such that at any given time each processing circuit 214 receives the same analog ramp voltage and the same digital ramp counter value. This is to ensure that any difference in the digital values output by different pixel cells is due to differences in the intensity of light received by the pixel cells, not due to mismatches in the digital ramp signals/counter values and analog ramp signals received by the pixel cells.

The image data from image sensor 200 can be transmitted to host processor (not shown in FIG. 2A-FIG. 2E) to support different applications, such as identifying and tracking object 252 or performing depth sensing of object 252 with respect to image sensor 200 depicted in FIG. 2F. For all these applications, only a subset of pixel cells provide relevant information (e.g., pixel data of object 252), whereas the rest of pixel cells do not provide relevant information. For example, referring to FIG. 2F, at time T0 a group of pixel cells 250 of image sensor 200 receive light reflected by object 252, whereas time T6, object 252 may have shifted (e.g., due to a movement of object 252, a movement of image sensor 200, or both), and a group of pixel cells 270 of image sensor 200 receive light reflected by object 252. At both times T0 and T6, image sensor 200 can transmit only the pixel data from group of pixel cells 260 and 270, as a sparse image frame, to the host processor to reduce the volume of pixel data being transmitted. Such arrangements can allow transmission of higher resolution images at a higher frame rate. For example, a larger pixel cell array including more pixel cells can be used to image object 252 to improve image resolution, while the bandwidth and power required to provide the improved image resolution can be reduced when only a subset of the pixel cells, including the pixel cells that provide pixel data of object 252, transmit the pixel data to the host processor. Similarly, image sensor 200 can be operated to generate images at a higher frame rate, but the increases in bandwidth and power can be reduced when each image only includes pixel values output by the subset of the pixel cells. Similar techniques can be employed by image sensor 200 in the case of 3D sensing.

The volume of pixel data transmission can also be reduced in the case of 3D sensing. For example an illuminator can project a pattern of structured light onto an object. The structured light can be reflected on a surface of an object and a pattern of reflected light can be captured by image sensor 200 to generate an image. Host processors can match pattern with object pattern and determine the depth of objects with respect to image sensor 200 based on the configuration of object pattern in the image. For 3D sensing, only groups of pixel cells contain relevant information (e.g., pixel data of pattern 252). To reduce the volume of pixel data being transmitted, image sensor 200 can be configured to send only the pixel data from groups of pixel cells or the image location locations of patterns in the image, to the host processor.

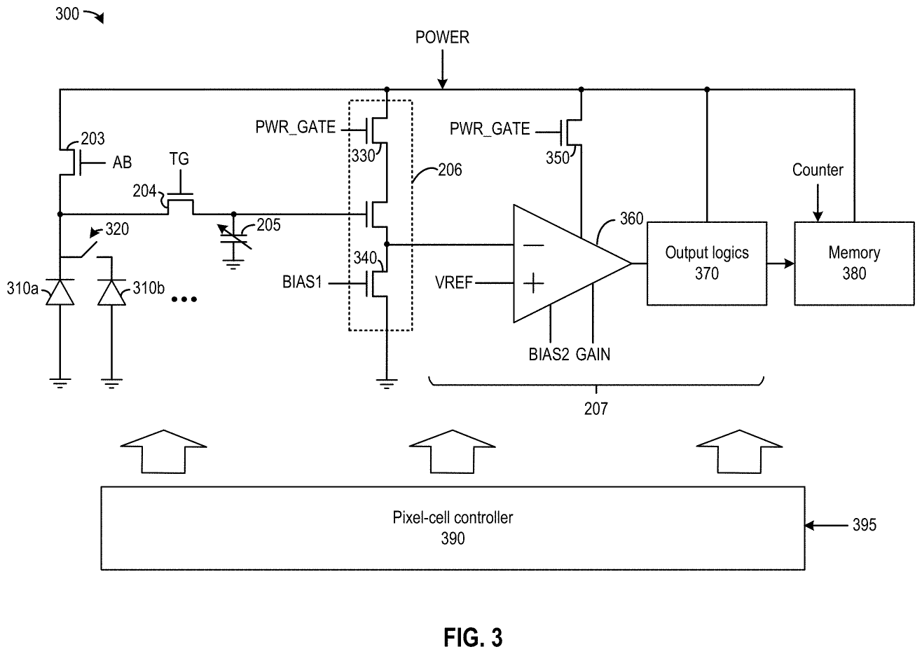

FIG. 3 illustrates example internal components of a pixel cell 300 of a pixel cell array, which can include at least some of the components of pixel cell 201 of FIG. 2A. Pixel cell 300 can include one or more photodiodes, including photodiodes 310a, 310b, etc., each can be configured to detect light of a different frequency range. For example, photodiode 310a can detect visible light (e.g., monochrome, or one of red, green, or blue color), whereas photodiode 310b can detect infra light. Pixel cell 300 further includes a switch 320 (e.g., a transistor, a controller barrier layer) to control which photodiode outputs charge for pixel data generation.

In addition, pixel cell 300 further includes electronic shutter switch 203, transfer switch 204, charge storage device 205, buffer 206, quantizer 207 as shown in FIG. 2A, as well as a memory 380. Charge storage device 205 can have a configurable capacitance to set a charge-to-voltage conversion gain. In some examples, the capacitance of charge storage device 205 can be increased to store overflow charge for FD ADC operation for a medium light intensity to reduce the likelihood of charge storage device 205 being saturated by the overflow charge. The capacitance of charge storage device 205 can also be decreased to increase the charge-to-voltage conversion gain for PD ADC operation for a low light intensity. The increase in the charge-to-voltage conversion gain can reduce quantization error and increase the quantization resolution. In some examples, the capacitance of charge storage device 205 can also be decreased during the FD ADC operation to increase the quantization resolution. Buffer 206 includes a current source 340 of which the current can be set by a bias signal BIAS1, as well as a power gate 330 which can be controlled by a PWR_GATE signal to turn on/off buffer 206. Buffer 206 can be turned off as part of disabling pixel cell 300.

In addition, quantizer 207 includes a comparator 360 and output logics 370. Comparator 207 can compare the output of buffer with a reference voltage (VREF) to generate an output. Depending on a quantization operation (e.g., time to saturation (TTS), FD ADC, and PD ADC operations), comparator 360 can compare the buffered voltage with different VREF voltages to generate the output, and the output be further processed by output logics 370 to cause memory 380 to store a value from a free running counter as the pixel output. The bias current of comparator 360 can be controlled by a bias signal BIAS2 which can set the bandwidth of comparator 360, which can be set based on the frame rate to be supported by pixel cell 300. Moreover, the gain of comparator 360 can be controlled by a gain control signal GAIN. The gain of comparator 360 can be set based on a quantization resolution to be supported by pixel cell 300. Comparator 360 further includes a power switch 350 which can also be controlled by the PWR_GATE signal to turn on/off comparator 360. Comparator 360 can be turned off as part of disabling pixel cell 300.

In addition, output logics 370 can select the outputs of one of the TTS, FD ADC, or PD ADC operations and based on the selection, determine whether to forward the output of comparator 360 to memory 380 to store the value from the counter. Output logics 370 can include internal memory to store indications, based on the output of comparator 360, of whether the photodiode 310 (e.g., photodiode 310a) is saturated by the residual charge, and whether charge storage device 205 is saturated by the overflow charge. If charge storage device 205 is saturated by the overflow charge, output logics 370 can select TTS output to be stored in memory 380 and prevent memory 380 from overwriting the TTS output by the FD ADC/PD ADC output. If charge storage device 205 is not saturated but the photodiodes 310 are saturated, output logics 370 can select the FD ADC output to be stored in memory 380; otherwise output logics 370 can select the PD ADC output to be stored in memory 380. In some examples, instead of the counter values, the indications of whether photodiodes 310 are saturated by the residual charge and whether charge storage device 205 is saturated by the overflow charge can be stored in memory 380 to provide the lowest precision pixel data.

In addition, pixel cell 300 may include a pixel-cell controller 390, which can include logic circuits to generate control signals such as AB, TG, BIAS1, BIAS2, GAIN, VREF, PWR_GATE, etc. Pixel-cell controller 390 can also be programmed by pixel-level programming signals 395. For example, to disable pixel cell 300, pixel-cell controller 390 can be programmed by pixel-level programming signals 395 to de-assert PWR_GATE to turn off buffer 206 and comparator 360. Moreover, to increase the quantization resolution, pixel-cell controller 390 can be programmed by pixel-level programming signals 395 to reduce the capacitance of charge storage device 205, to increase the gain of comparator 360 via GAIN signal, etc. To increase the frame rate, pixel-cell controller 390 can be programmed by pixel-level programming signals 395 to increase BIAS1 signal and BIAS2 signal to increase the bandwidth of, respectively, buffer 206 and comparator 360. Further, to control the precision of pixel data output by pixel cell 300, pixel-cell controller 390 can be programmed by pixel-level programming signals 395 to, for example, connect only a subset of bits (e.g., most significant bits) of the counter to memory 380 so that memory 380 only stores the subset of bits, or to store the indications stored in output logics 370 to memory 380 as the pixel data. In addition, pixel-cell controller 390 can be programmed by pixel-level programming signals 395 to control the sequence and timing of AB and TG signals to, for example, adjust the exposure period and/or select a particular quantization operation (e.g., one of TTS, FD ADC, or PD ADC) while skipping the others based on the operation condition, as described above.

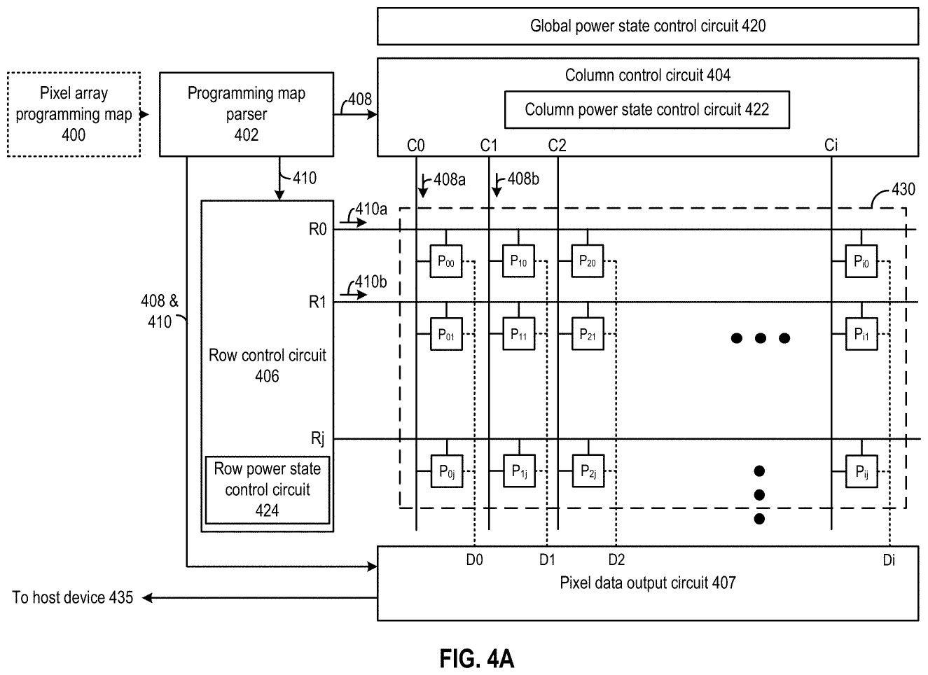

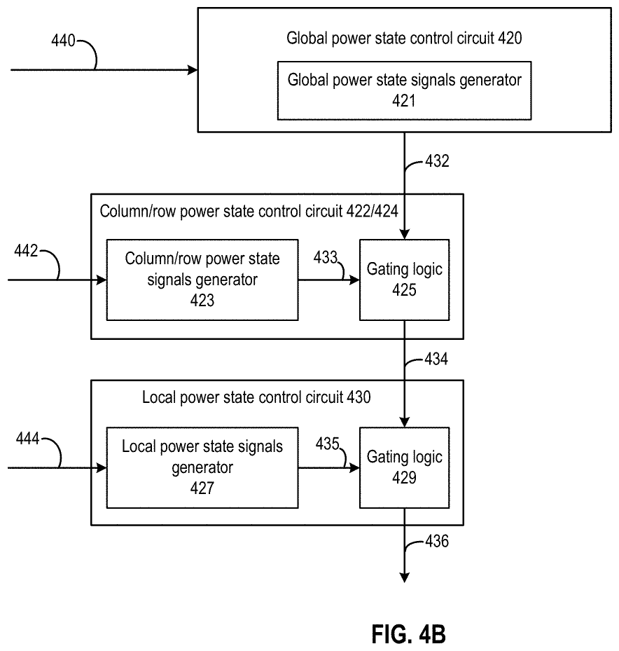

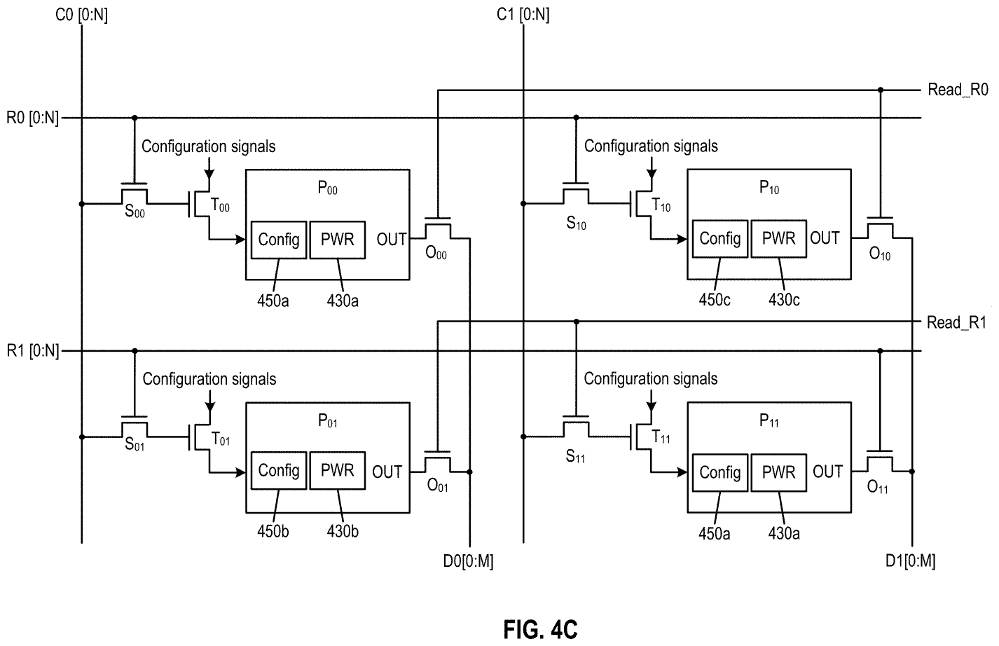

FIG. 4A, FIG. 4B, and FIG. 4C illustrate example components of a peripheral circuit and pixel cell array of an image sensor, such as image sensor 200. As shown in FIG. 4A, an image sensor can include a programming map parser 402, a column control circuit 404, a row control circuit 406, and a pixel data output circuit 407. Programming map parser 402 can parse pixel array programming map 400, which can be in a serial data stream, to identify the programming data for each pixel cell (or block of pixel cells). The identification of the programming data can be based on, for example, a pre-determined scanning pattern by which the two-dimensional pixel array programming map is converted into the serial format, as well as the order by which the programming data is received by programming map parser 402 from the serial data stream. Programming map parser 402 can create a mapping among the row addresses of the pixel cells, the column addresses of the pixel cells, and one or more configuration signals based on the programming data targeted at the pixel cells. Based on the mapping, programming map parser 402 can transmit control signals 408 including the column addresses and the configuration signals to column control circuit 404, as well as control signals 410 including the row addresses mapped to the column addresses and the configuration signals to row control circuit 406. In some examples, the configuration signals can also be split between control signals 408 and control signals 410, or sent as part of control signals 410 to row control circuit 406.

Column control circuit 404 and row control circuit 406 are configured to forward the configuration signals received from programming map parser 402 to the configuration memory of each pixel cell of pixel cell array 318. In FIG. 4A, each box labelled (e.g., P₀₀, P₀₁, P₁₀, P₁₁) can represent a pixel cell or a block of pixel cells (e.g., a 2×2 array of pixel cells, a 4×4 array of pixel cells) and can include or can be associated with a quantization circuit 220 of FIG. 2E comprising processing circuits 214 and memory 216. As shown in FIG. 4A, column control circuit 404 drives a plurality of sets of column buses C0, C1, . . . Ci. Each set of column buses includes one or more buses and can be used to transmit control signals, which can include a column selection signal and/or other configuration signals, to a column of pixel cells. For example, column bus(es) C0 can transmit a column selection signal 408a to select a column of pixel cells (or a column of blocks of pixel cells) p₀₀, p₀₁, . . . p₀ⱼ, column bus(es) C1 can transmit a column selection signal 408b to select a column of pixel cells (or blocks of pixel cells) p₁₀, p₁₁, . . . pᵢⱼ, etc.

Further, row control circuit 406 drives a plurality of sets of row buses labelled R0, R1, . . . Rj. Each set of row buses also includes one or more buses and can be used to transmit control signals, which can include a row selection signal and/or other configuration signals, to a row of pixel cells, or a row of blocks of pixel cells. For example, row bus(es) R0 can transmit a row selection signal 410a to select a row of pixel cells (or blocks of pixel cells) p₀₀, p₁₀, . . . pᵢ₀, row bus(es) R1 can transmit a row selection signal 410b to select a row of pixel cells (or blocks of pixel cells) p₀₁, p₁₁, . . . p₁ᵢ, etc. Any pixel cell (or block of pixel cells) within pixel cell array 318 can be selected based on a combination of the row selection signal and the column signal to receive the configuration signals. The row selection signals, column selection signals, and the configuration signals (if any) are synchronized based on control signals 408 and 410 from programming map parser 402, as described above. Each column of pixel cells can share a set of output buses to transmit pixel data to pixel data output circuit 407. For example, column of pixel cells (or blocks of pixel cells) p₀₀, p₀₁, . . . p₀ⱼ can share output buses Do, column of pixel cells (or blocks of pixel cells) p₁₀, p₁₁, . . . p₁ⱼ can share output buses D₁, etc.

Pixel data output circuit 407 can receive the pixel data from the buses, convert the pixel data into one or more serial data streams (e.g., using a shift register), and transmit the data streams to host device 435 under a pre-determined protocol such as MIPI. The data stream can come from a quantization circuit 220 (e.g., processing circuits 214 and memory 216) associated with each pixel cell (or block of pixel cells) as part of a sparse image frame. In addition, pixel data output circuit 407 can also receive control signals 408 and 410 from programming map parser 402 to determine, for example, which pixel cell does not output pixel data or the bit width of pixel data output by each pixel cell, and then adjust the generation of serial data streams accordingly. For example, pixel data output circuit 407 can control the shift register to skip a number of bits in generating the serial data streams to account for, for example, variable bit widths of output pixel data among the pixel cells or the disabling of pixel data output at certain pixel cells.

In addition, a pixel cell array control circuit further includes a global power state control circuit, such as global power state control circuit 420, a column power state control circuit 422, a row power state control circuit 424, and a local power state control circuit 430 at each pixel cell or each block of pixel cells (not shown in FIG. 4A) forming hierarchical power state control circuits. Global power state control circuit 420 can be of the highest level in the hierarchy, followed by row/column power state control circuit 422/424, with a local power state control circuit 430 at the lowest level in the hierarchy.

The hierarchical power state control circuits can provide different granularities in controlling the power state of an image sensor, such as image sensor 200. For example, global power state control circuit 420 can control a global power state of all circuits of image sensor, including processing circuits 214 and memory 216 of all pixel cells, DAC 242 and counter 240 of FIG. 2E, etc. Row power state control circuit 424 can control the power state of processing circuits 214 and memory 216 of each row of pixel cells (or blocks of pixel cells) separately, whereas column power state control circuit 422 can control the power state of processing circuits 214 and memory 216 of each column of pixel cells (or blocks of pixel cells) separately. Some examples may include row power state control circuit 424 but not column power state control circuit 422, or vice versa. In addition, a local power state control circuit 430 can be part of a pixel cell or a block of pixel cells, and can control the power state of processing circuits 214 and memory 216 of the pixel cell or the block of pixel cells.

FIG. 4B illustrates examples of internal components of hierarchical power state control circuits and their operations. Specifically, global power state control circuit 420 can output a global power state signal 432, which can be in the form of a bias voltage, a bias current, a supply voltage, or programming data, that sets a global power state of the image sensor. Moreover, column power state control circuit 422 (or row power state control circuit 424) can output a column/row power state signal 434 that sets a power state of a column/row of pixel cells (or blocks of pixel cells) of the image sensor. Column/row power state signal 434 can be transmitted as row signals 410 and column signals 408 to the pixel cells. Further, local power state control circuit 430 can output a local power state signal 436 that sets a power state of the pixel cell (or a block of pixel cells), including the associated processing circuits 214 and memory 216. Local power state signal 436 can be output to processing circuits 214 and memory 216 of the pixel cells to control their power state.

In hierarchical power state control circuits, an upper-level power state signal can set an upper bound for a lower-level power state signal. For example, global power state signal 432 can be an upper level power state signal for column/row power state signal 434 and set an upper bound for column/row power state signal 434. Moreover, column/row power state signal 434 can be an upper level power state signal for local power state signal 436 and set an upper bound for local power state signal 436. For example, if global power state signal 432 indicates a low power state, column/row power state signal 434 and local power state signal 436 may also indicate a low power state.

Each of global power state control circuit 420, column/row power state control circuit 422/424, and local power state control circuit 430 can include a power state signal generator, whereas column/row power state control circuit 422/424, and local power state control circuit 430 can include a gating logic to enforce the upper bound imposed by an upper-level power state signal. Specifically, global power state control circuit 420 can include a global power state signals generator 421 to generate global power state signal 432. Global power state signals generator 421 can generate global power state signal 432 based on, for example, an external configuration signal 440 (e.g., from a host device) or a pre-determined temporal sequences of global power states.

In addition, column/row power state control circuit 422/424 can include a column/row power state signals generator 423 and a gating logic 425. Column/row power state signals generator 423 can generate an intermediate an column/row power state signal 433 based on, for example, an external configuration signal 442 (e.g., from a host device) or a predetermined temporal sequences of row/column power states. Gating logic 425 can select one of global power state signal 432 or intermediate column/row power state signal 433 representing the lower power state as column/row power state signal 434.

Further, local power state control circuit 430 can include a local power state signals generator 427 and a gating logic 429. Low power state signals generator 427 an intermediate local power state signal 435 based on, for example, an external configuration signal 444, which can be from a pixel array programming map, a pre-determined temporal sequences of row/column power states, etc. Gating logic 429 can select one of intermediate local power state signal 435 or column/row power state signal 434 representing the lower power state as local power state signal 436.

FIG. 4C illustrates additional details of a pixel cell array, including local power state control circuit 430 (e.g., 430a, 430b, 430c, and 430d, labelled as “PWR” in FIG. 4C) and configuration memory 450 (e.g., 450a, 450b, 450c, and 450d, labelled as “Config” in FIG. 4C) of each pixel cell (or each block of pixel cells). Configuration memory 450 can store first programming data to control a light measurement operation (e.g., exposure period duration, quantization resolution) of a pixel cell (or a block of pixel cells). In addition, configuration memory 450 can also store second programming data that can be used by local power state control circuit 430 to set the power states of processing circuits 214 and memory 216. Configuration memory 450 can be implemented as a static random-access memory (SRAM). Although FIG. 4C shows that local power state control circuit 430 and configuration memory 450 are internal to each pixel cell, it is understood that configuration memory 450 can also be external to each pixel cell, such as when local power state control circuit 430 and configuration memory 450 are for a block of pixel cells.

As shown in FIG. 4C, the configuration memory 450 of each pixel cell is coupled with column buses C and row buses R via transistors S, such as S₀₀, S₁₀, S₁₀, S₁₁, etc. In some examples, each set of column buses (e.g., C0, C1) and row buses (e.g., R0, R1) can include multiple bits. For example, in FIG. 4C, each set of column buses and row buses can carry N+1 bits. It is understood that in some examples each set of column buses and row buses can also carry a single data bit. Each pixel cell is also electrically connected with transistors T, such as T₀₀, T₁₀, T₁₀, or T₁₁, to control the transmission of configuration signals to the pixel cell (or block of pixel cells). Transistor(s) S of each pixel cell can be driven by the row and column select signals to enable (or disable) the corresponding transistors T to transmit configuration signals to the pixel cell. In some examples, column control circuit 404 and row control circuit 406 can be programmed by a single write instruction (e.g., from a host device) to write to configuration memory 450 of multiple pixel cells simultaneously. Column control circuit 404 and row control circuit 406 can then control the row buses and column buses to write to the configuration memory of the pixel cells.

In some examples, local power state control circuit 430 can also receive configuration signal directly from transistors T without storing the configuration signals in configuration memory 450. For example, as described above, local power state control circuit 430 can receive row/column power state signal 434, which can be an analog signal such as a voltage bias signal or a supply voltage, to control the power state of the pixel cell and the processing circuits and/or memory used by the pixel cell.

In addition, each pixel cell also includes transistors O, such as O₀₀, O₁₀, O₁₀, or O₁₁, to control the sharing of the output bus D among a column of pixel cells. The transistors O of each row can be controlled by a read signal (e.g., read_R0, read_R1) to enable a row-by-row read out of the pixel data, such that one row of pixel cells output pixel data through output buses D0, D1, . . . Di, followed by the next row of pixel cells.

In some examples, the circuit components of a pixel cell array, including processing circuits 214 and memory 216, counter 240, DAC 242, buffer network including buffers 230, etc., can be organized into a hierarchical power domain managed by hierarchical power state control circuits. The hierarchical power domain may include a hierarchy of multiple power domains and power sub-domains. The hierarchical power state control circuits can individually set a power state of each power domain, and each power sub-domain under each power domain. Such arrangements allow fine grain control of the power consumption by image sensor 304 and support various spatial and temporal power state control operations to further improve the power efficiency of an image sensor.

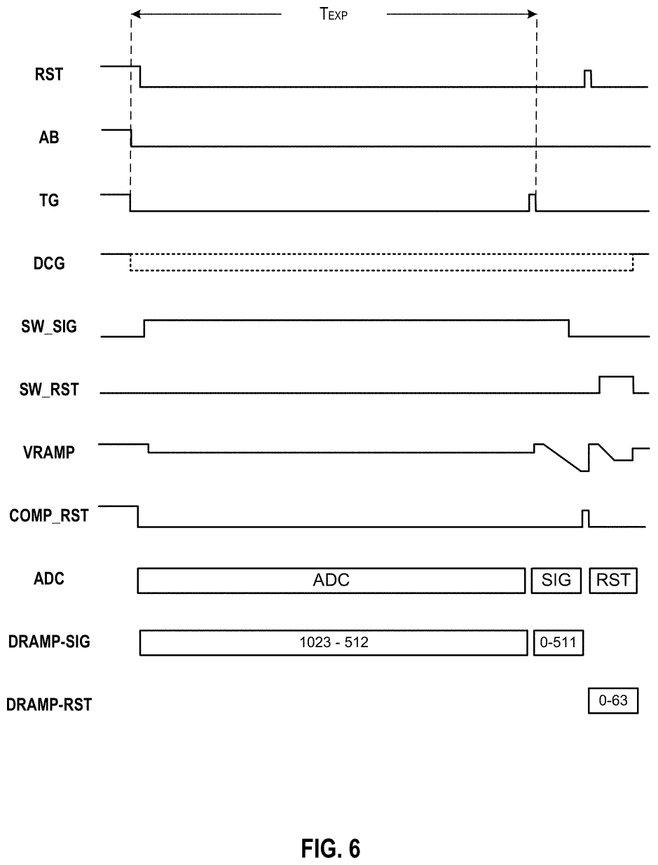

While a sparse-image sensing operation can reduce the power and bandwidth requirement, having pixel-level ADCs (e.g., as shown in FIG. 6C) or block-level ADCs (e.g., as shown in FIG. 2E) to perform the quantization operations for the sparse-image sensing operation can still lead to inefficient use of power. Specifically, while some of the pixel-level or block-level ADCs are disabled, high speed control signals, such as clocks, analog ramp signals, or digital ramp signals, may still be transmitted to each pixel-level or block-level ADCs via buffer network 630, which can consume a substantial amount of power and increase the average power consumption for generation of each pixel. The inefficiency can be further exacerbated when the sparsity of the image frame increases (e.g., containing fewer pixels), but the high speed control signals are still transmitted to each pixel cell, such that the power consumption in transmitting the high speed control signals remains the same and the average power consumption for generation of each pixel increases due to fewer pixels being generated.

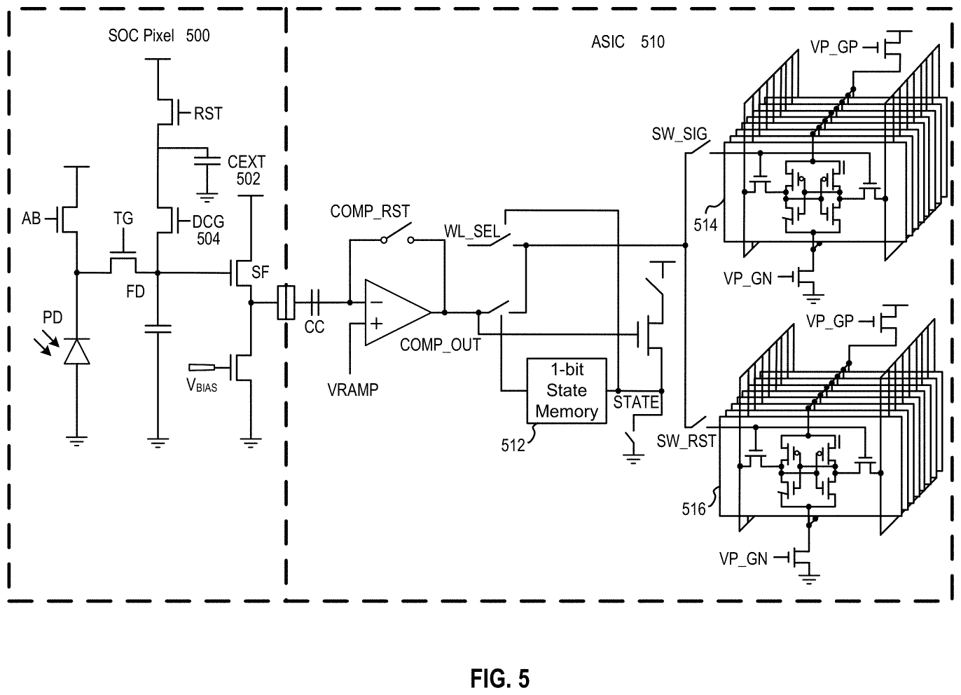

FIG. 5 illustrates an example of a pixel cell and integrated circuit for pixel-specific fixed pattern noise reduction. Specifically, FIG. 5 depicts an example of digital image sensor apparatus for performing the embodiments described herein. SOC pixel 500 may be a pixel cell configured to generate a charge in a photodiode, similar to pixel cell 201 depicted in FIG. 2A and FIG. 2C. For example, SOC pixel 500 included components of the pixel cell 201 such as components 201-206 and others.

The pixel cell depicted in FIG. 5 includes an SOC pixel 500 and an ASIC 510 coupled together as part of a pixel domain. SOC pixel 500 and ASIC 510 may be configured to operate in conjunction to convert a charge generated by captured light and FPN to a plurality of digital pixel values. For example, the photodiode (depicted as PD) first receives light and outputs a generated charge, which accumulates to one or more capacitors or other charge storage devices. The charges stored in by the capacitors is then converted to a pixel value by the ASIC 510 and stored in a plurality of SRAMs in the ASIC 510.

The configuration shown in FIG. 5 will enable a pixel-domain to reduce pixel pattern noise generated by a pixel-domain that will alter the signal generated by the captured of light at the photodiode. For example the charge captured by the capacitors will be passed to a comparator, which will compare the charge to a reference voltage that determine a corresponding digital pixel value. The digital pixel value will be sent to a first SRAM in the ASIC 510. Because the captured voltage value inherently contains FPN generated by the environment, the SOC pixel 500, the ASIC 510, and any other components/latent defects in the components, the first digital pixel value stored in the SRAM corresponds to both the charge generated by the photodiode and the FPN.

Once the first digital pixel value is determined, a reset signal may “pulse” in the pixel domain, purging the circuits of previously accumulated charges. For example, the charge storage devices in the SOC pixel 500 and ASIC 510, as well as the comparator in the ASIC 510 may be reset to an original state. Though the reset has purged most of the charge in the pixel-domain, latent voltage signals continue to exist in the circuit due to environmental noise, residual charge, and defects in the individual components. Thus, this latent FPN noise can be captured and stored as a second digital pixel value in a second SRAM. The difference between the first digital pixel value and the second digital pixel value will then closely represent the charge generated by the photodiode absent the FPN.

A pixel cell, such as SOC pixel 500, may contain an additional charge storage device, to enable low-gain charge conversion in the pixel cell. For example, as depicted in FIG. 5, SOC pixel 500 includes CEXT capacitor 502. CEXT capacitor 502 may operate in conjunction with an additional gate, such as a dual conversion gate (DCG) 504. CEXT capacitor 502 may be a capacitor or other charge storage device configured within the SOC pixel to enable the SOC pixel to switch between a high-gain (when DCG gate 504 is open) and a low-gain (when DCG gate 504 is closed) charge generation operating configuration. For example, in a high-gain charge generation operating configuration, DCG gate 504 may be open, interrupting signals from the photodiode to CEXT capacitor 502. In this configuration, the SOC pixel 500 operates similarly to pixel cell 201. When the DCG gate 504 is closed, signals from the photodiode reach CEXT capacitor 502 via the closed circuit and CEXT capacitor 502 may store a charge in a low-conversion gain configuration.

While CEXT capacitor 502 improves high-light (or low-gain light) collection, the additional capacitor may take up valuable space on a compressed circuit and may generate noise that will increase the FPN of the circuit. In some embodiments, CEXT capacitor 502 is removed from SOC pixel 500 and DCG gate 504 remains in the SOC pixel. In this configuration, the DCG gate 504 may continue to switch between and open and closed state, but there will not be a capacitor the convert and store charge for low-power operations. This allows the SOC pixel to switch between a high-gain (when DCG gate 504 is open) and a medium-gain (when DCG gate 504 is closed) charge generation operating configuration. Thus, when the DCG gate 504 is open, the SOC pixel continues to operate in a high-gain mode as before, but when the DCG gate 504 is closed, the SOC pixel 500 will now convert and stored charges using a moderate gain configuration.

Like CEXT 502, DCG gate 504 may be removed from the SOC pixel 500 to increase the amount of space available to a compressed circuit and reduce noise generated by the DCG gate 504. In this configuration, SOC pixel 500 will only generate charges in a high-gain charge generation operating configuration. However, the amount of space available to the SOC pixel is increased and the amount of FPN generated by components of the SOC pixel 500 is reduced. It will be appreciated that any subset of pixels in the pixel array may use any of the above configurations to suit the needs of the digital image sensor.

ASIC 510 is an application-specific integrated circuit coupled to SOC pixel 500 to form a pixel domain corresponding to a pixel of the digital image sensor. As depicted in FIG. 5, ASIC 510 may include a secondary charge storage device, such as a capacitor to perform correlated double sampling, a comparator configured to compare a stored charge from the SOC pixel (and/or the secondary charge storage device) to a reference voltage ramp. The comparator include a switch for resetting the comparator and is coupled to a 1-bit state memory 512. 1-bit state memory 512 may be a logical circuit configured to intake an output signal from the comparator and determine whether to forward a stored charge to one or more SRAM or other memory circuits within the ASIC 510. For example, as depicted in FIG. 5, 1-bit state memory 512 may intake the output of the comparator and output a state signal to control one or more memory switches.

As depicted in FIG. 5, a first SRAM, signal SRAM 514 is coupled to the rest of ASIC 510 via a signal switch. The signal switch may be activated according to an output state of 1-bit state memory 512. For example, 1-bit state memory 512 may output a state indicating that the SOC pixel is currently undergoing an exposure period. The 1-bit state memory 512 may send a signal to close the signal switch and close a circuit between signal SRAM 514 and the rest of ASIC 510. Thus, the charge being stored and converted by the pixel domain may be sent to signal SRAM 514 to store later output the stored charge as a digital pixel value.

As further depicted in FIG. 5, a second SRAM, reset SRAM 516 is coupled to the rest of ASIC 510 via a reset switch. The reset switch may be activated according to an output state of 1-bit state memory 512. For example, 1-bit state memory 512 may output a state indicating that the SOC pixel has undergone a reset and the pixel domain is currently generating a charge from latent fixed-pattern noise. The 1-bit state memory 512 may send a signal to close the reset switch and close a circuit between reset SRAM 516 and the rest of ASIC 510. Thus, the charge being latently generated by the pixel domain as FPN may be sent to reset SRAM 516 to store and later output as a digital pixel value.

FIG. 6 illustrates a timing diagram depicting a time sequence of component activities during a charge capture time period. Specifically, FIG. 6 depicts the timing signals of the components of a pixel domain in the digital image sensor during the adaptive noise reduction techniques described herein. The timing diagram illustrated in FIG. 6 depicts the timing of the circuits in an individual pixel domain an overall frame capture time period.

As depicted in FIG. 6, the beginning of the timing diagram may follow a reset state triggered at the pixel domain to prepare the SOC pixel 500 and ASIC 510 for a new frame capture. Thus, the reset of gate of the SOC pixel 500 is currently in a high state. The reset gate enters a low state shortly after a time period of exposure of the charge storage device (depicted in FIG. 6 as T_{EXP}). After the time period of exposure has finished, the reset gate may be pulsed to reset the pixel domain in order to generate and store a charge corresponding to FPN inherent to the pixel domain. The reset gate may then be reset as high for a next frame capture (not depicted in FIG. 6). Prior to the time period of exposure, an electronic shutter switch (such as electronic shutter switch 203) and a transfer switch (such as transfer switch 204) are engaged in a high state and transition to a low state during the exposure period. The transfer switch will pulse just prior to the end of the exposure period to signal the end of the period.

In embodiments that implement a DCG gate, such as DCG gate 504, the gate may be set to either an high state or a low state during the time period of exposure. For example, in embodiments, where a moderate-gain (or low-gain in embodiment further implementing a CEXT capacitor 502), charge storage configuration is desired, the DCG gate 504 may be set to a closed configuration state so that charge may pass through the DCG gate 504 to enable the lower-gain configuration.

Shortly following the beginning of the period of exposure, the signal switch to signal SRAM 514 will enter a high power state to enable charge to begin flowing to the SRAM. The SRAM may contain circuits for storing the charge sent to the signal SRAM 514 during this time period by the comparator after it has compared the analog voltage to the reference ramp voltage value. The switch will reenter a low power state shortly after the exposure period ends.

As depicted in FIG. 6, during a first time period, the pixel cell may capture and convert light to a charge, for example, as part of a TTS operation. During the first time period, the SOC pixel may be exposed to light in order to generate and quantize a charge (represented by Tₑₓₚ). For example, the DRAMP-SIG value of 1023-512 represents a 9-bit resolution analog-to-digital conversion with one flag bit for quantizing the TTS operation. At the end of the exposure period, the TG gate may be pulsed to transfer charges in a photodiode to a charge storage device (e.g., CEXT 502, FD, CC, etc.) and begin a signal conversion. For example, the DRAMP-SIG value of 0-511 represents a standard 9-bit analog-to-digital conversion of the stored charge.

Shortly after the exposure period ends and the signal switch is opened, the reset gate will pulse signaling the reset switch of the reset SRAM 516 to enter a high power state. During this period, the reset SRAM 516 will receive charge converted and stored by FPN generated latently by the environment and the pixel domain. During this time, the charge storage device is not coupled to the photodiode and charges from light will not be converted and stored. This will provide the reset SRAM 516 with an isolated FPN signal quantized by the comparator based on the reference ramp voltage. For example, the DRAMP-RST value of 0-63 represents a standard 6-bit analog-to-digital conversion of the FPN signal to a digital pixel value. The value is stored in the reset SRAM 516 as a digital pixel value representing the digital FPN generated latently by the pixel domain.

As depicted in FIG. 6, the VRAMP voltage supplied to the comparator of ASIC 510 may switch from a high power state moderate power state during the time period of exposure, and may pulse and ramp down during the conversion of the analog voltage values by the ADC. A comparator reset may occur along with the reset gate pulsing in order to reset the comparator in order to measure the FPN. The comparator is often a source of FPN within the ASIC and resetting the comparator during the second time period is important to generate a reliable FPN signal.

An ADC that will convert the generated charge values is inactive during the time period of exposure. Following the first time period of exposure the ADC will begin converting the generated signal voltage value to a digital value. The digital value may be based on a DRAMP signal configuration which will convert the value to a 9-bit number. Following the conversion of the generated signal volume value to a digital value by the ADC, the ADC will then convert the generated reset voltage value to a digital value. The digital value may be based on a DRAMP reset configuration which will convert the value to a 6-bit number. Following these operations, the pixel cell may again be reset and a new frame capture will begin.

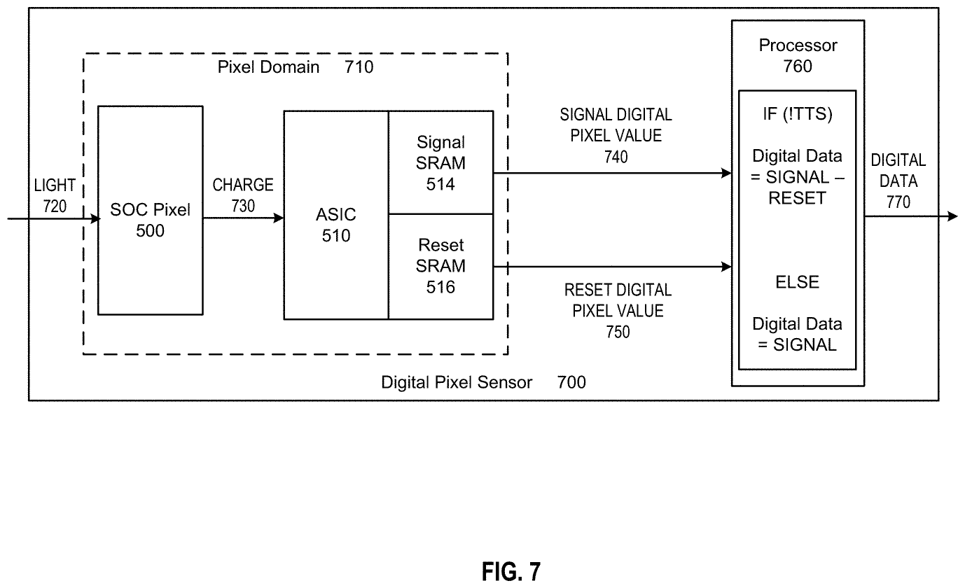

FIG. 7 illustrates a digital pixel sensor and flow diagram for receiving light as input and outputting digital data. More specifically, FIG. 7 depicts a flow of data signals through components of a digital pixel sensor 700 from the input of light to the output of digital data. Digital pixel sensor contains SOC pixel 500 and ASIC 510. ASIC 510 in connected to or contains signal SRAM 514 and reset SRAM 516. SOC pixel 500, ASIC 510 and the SRAM memories 514-516 make up pixel domain 710 of digital pixel sensor 700.

At the beginning of the flow, light 720 enters SOC pixel 500, for example through a photodiode such as photodiode 202. The photodiode is configured to generate a charge in response to light and a charge storage device, such as charge storage device 206 in configured to convert and store a charge based on the generated charge. The charge storage device may send this charge to ASIC 510, for example as part of a charge 730. ASIC 510 may receive charge 730 and quantize the charges, which may be stored at either of signal SRAM 514 or reset SRAM 516 according to the time period during which the charge is received. For example, if the charge 730 is received during the exposure period, the charge 730 will be received, quantized, and then stored by signal SRAM 514. If the charge 730 is received during the reset period (during which the latent FPN is measured), the charge will be received, quantized, and then stored by reset SRAM 516.

The output of signal SRAM 514 and reset SRAM 516 are digital pixel values signal digital pixel value 740 and reset digital pixel value 750 respectively. Signal digital pixel value 740 may be, for example, a digital pixel value determined by a comparator and stored in memory circuits of signal SRAM 514 during the exposure time period, and represents the charge converted from the reception of light 720 and additional FPN generated by the pixel domain 710. Reset voltage 750 may be, for example, a digital pixel value determined by a comparator and stored in memory circuits of reset SRAM 516 during the reset period and represents FPN voltage values generated by latent signals within the circuit during the reset period.

Each of signal digital pixel value 740 and reset digital pixel value 750 are sent to a processor 760 for further processing the digital pixel values after quantization and storage. The processor may include, for example, logical instructions configured to determine if a value received from the pixel domain 710 was generated as part of an initial TTS or similar operation, or during a subsequent time period. For example, the processor 760 may forward the signal digital pixel value 740 if it was generated as part of a TTS operation (e.g., prior to the pulsing of the TG gate). However, as described herein, the quantized digital pixel value from the TTS operation may not be strong enough to sufficiently “drown out” latent FPN from the pixel domain 710 when utilized in downstream applications. Accordingly, processor 760 may determine to perform a digital pixel value conversion based on separate signal and reset digital pixel values received after performing the TTS operation. For example, the processor 760 may determine that a signal digital pixel value 740 is not a TTS-based value (e.g., a value quantized after pulsing the TG gate, but before pulsing the RST gate), and responsively perform a digital pixel value conversion on the signal value (e.g., generating a third digital pixel value based on the difference between the quantized signal value the quantized reset value). The digital data 770 may thus be indicative of a quantized TTS operation or a quantized conversion value correcting for latent FPN in the pixel domain 710.

It will be appreciated that the comparisons performed by the processor 760 may be performed by logical circuits in the pixel cell 500 or ASIC 510 in some embodiments. In various embodiments, the processor 760 may determine to perform the conversion of the digital pixel value based on a threshold value of sufficient charge capture and quantization. As discussed herein, the threshold pixel value may represent a value at which a quantized signal value sufficiently outweighs pixel pattern noise generated within a pixel domain (e.g., whether the quantized digital pixel value from the TTS operation sufficiently “drowns out” latent FPN). In various further embodiments, the conversion of the digital pixel value is performed when it is determined that the quantized signal digital pixel value 740 (e.g., the TTS-based value) does not meet the threshold. This may correspond to a situation in which the loss of power required to remove the FPN from the digital pixel data using the digital pixel value conversion is not worth the value of the relative correction of the FPN in the final digital data (e.g., the captured light intensity during the TTS operation is so intense that a reduction of FPN would be negligible in the final digital data exported). In some embodiments, the ADC does not quantize the reset voltage charge (e.g. when the SW RST is not closed) if the processor 760 has determined that the digital pixel value for the TTS signal has met or exceeded the threshold voltage. In some embodiments, the ADC will quantize the reset voltage signal in response to a signal from the processor 760 that the threshold voltage is not met by the TTS operation. Thus the ADC will consume power to quantize a reset voltage signal when necessary to correct potentially corrupted values generated during the TTS operation. In some embodiments, the processor 760 may compile digital image data using digital pixel values from a variety of TTS operations performed by a number of pixel domains. The processor may then regenerate the digital pixel data by replacing digital pixel values that do not meet the threshold with the converted digital pixel values from the signal and reset operations. The digital data 770 resulting from processor by the processor 760 is output by the digital pixel sensor 700. Thus, the processor 760 may perform pixel conversions as necessary to improve a digital image to save power, as opposed to universally performing pixel conversions to replace all TTS-based digital pixel values generated. More specifically, the processor 760 will may only replace those TTS-based values that did not meet the threshold value to save power while improving the generated digital image.

In some embodiments not pictured in FIG. 7, digital pixel sensor 700 may contain a periphery subsystem or processor configured to alter the digital data 770 prior to export off-sensor. For example, the periphery may perform one or more additional digital pixel value alterations prior to export of the digital data 770 off-sensor. The one or more additional alterations may include, for example, a universal application of a masking function to the digital image data (e.g., a scalar brightness reduction operation), a universal pixel value conversion mapping (e.g., a conversion of the data to grayscale), an additional FPN removal operation (e.g., an application of an software-specific mapping conversion, such as an overlay for an AR application), etc.

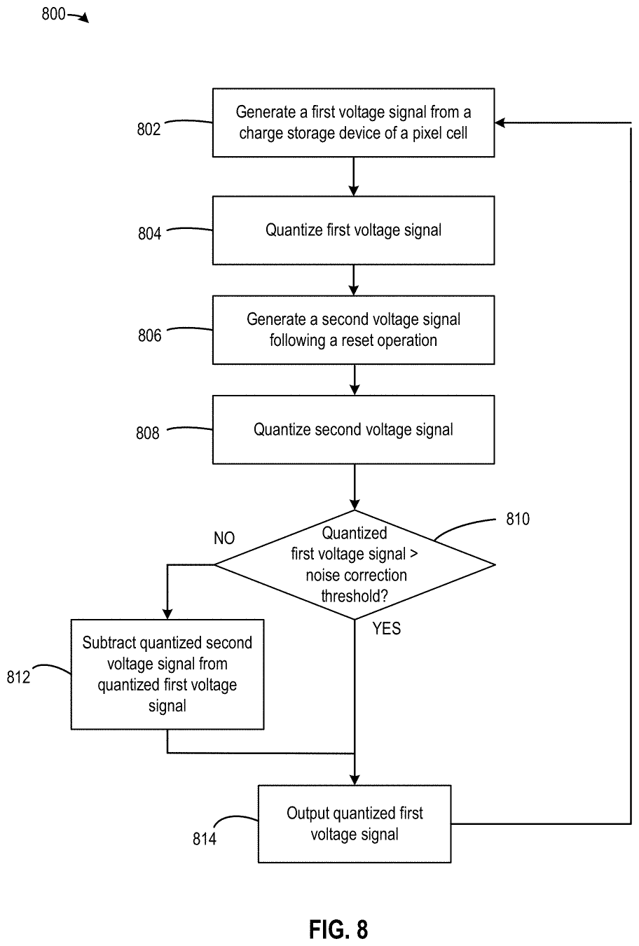

FIG. 8 illustrates an example process for pixel specific fixed pattern noise reduction utilizing a noise correction threshold. Specifically, FIG. 8 depicts a flowchart generating a signal voltage value and reset voltage value to reduce FPN output by a pixel domain as described herein. Process 800 may begin at 802, where a first voltage signal in generated from a charge storage device of a pixel cell. For example, a charge storage device, such as charge storage device 206 may receive a charge generated by a photodiode 202 in response to light. The charge may be voltage signal may be generated during a first period of time during which the charge storage device, signal SRAM, and photodiode are connected in a complete closed circuit.

At 804, the first voltage is quantized, for example, by an ADC. For example, the ADC may receive the signal voltage stored by charge storage device and quantize the signal voltage to generate a digital pixel value. The digital pixel value generated by the quantization operation may be based on a digital bit-based conversion scheme in signal SRAM 514. For example, as depicted in FIG. 6, the ADC may use a DRAMP signal to convert the first voltage signal to a 9-bit digital value. The resulting digital pixel value is a digital representation of the intensity of the light captured by the photodiode during the exposure period, but may also include latent FPN signals generated by the pixel domain during exposure.

At 806, a second voltage signal is generated following a reset operation. For example, a reset SRAM, such as reset SRAM 516 may receive a latent voltage signal from the pixel domain used to generate the first voltage signal in 802 following a reset of the pixel domain. The generated second voltage signal following the reset operation may represent an signal of FPN generated inherently by the pixel domain and the environment in which the digital image sensor is operating. For example, a reset gate and a comparator reset switch may trigger, purging the pixel domain circuit of charges used to generate the first voltage signal. Any resulting signals generated after the purge and before the next exposure period may correspond to a latent FPN within the pixel domain.

At 808, the second voltage is quantized, for example, by an ADC. For example, the ADC may receive the reset voltage generated latently by the pixel domain and quantize the reset voltage to generate a digital pixel value. The digital pixel value generated by the quantization operation may be based on a digital bit-based conversion scheme in reset SRAM 516. For example, as depicted in FIG. 6, the ADC may use a DRAMP signal to convert the second voltage signal to a 6-bit digital value. The resulting digital pixel value is a digital representation of the latent FPN generated by the pixel domain.

At 810, a determination is made whether the quantized first voltage signal is greater than a noise correction threshold. The determination may be performed by a processing circuit or subsystem of the digital pixel sensor such as processor 760. For example, processor 760 may receive, from an ADC, digital pixel data quantized by the ADC at 806. The processor 760 may also receive or have stored thereon a noise correction threshold (threshold pixel value). The threshold may correspond to a digital pixel value representing an intensity of captured charge for which correction of FPN would not be preferable given the power consumed by a quantization of the second voltage signal generated in 804 and an alteration operation to remove the FPN by determining the difference of two digital pixel values. For example, a highly intense light will only contain a small proportion of FPN in the corresponding digital pixel value, and removal of the FPN from the signal will only cause a negligible change in the resulting pixel while consuming a fixed amount of power. Thus, if the quantized first voltage signal is greater than the set noise correction threshold, the FPN need not be removed from the digital pixel value prior to export off-sensor.

In various embodiments, the processor 780 or a correlated component of digital pixel sensor 700 may receive, determine or otherwise generate the noise correction threshold. A noise correction threshold may be generated based on a state of the environment and a configuration of pixel cells in the array of pixel cells in the digital image sensor. For example, a bright environment (as measured by a sensor), and highly sensitive digital pixel sensor may cause the processor to generate a noise correction threshold that is relatively low to reduce the number of quantization operations and the number of digital pixel value alterations to save power. In some embodiments, the noise correction threshold may be determined based on a mean, median, mode or other value determined by a component of the digital pixel sensor. For example, a processor may determine a mean value of FPN during a previous frame using digital pixel values using quantized second voltage signal generated after a reset period.

If the quantized signal exceeds the noise correction threshold, the method proceeds to block 814, otherwise, it proceeds to block 812.

At 814, if it is determined that the quantized first voltage signal is greater than the noise corrections threshold, the quantized first voltage signal is output. In this case, the processor or another component of the digital pixel sensor may output the quantized first voltage signal as digital pixel data without any alternations, as an alteration of the digital pixel value quantized would consume more power than the conversion is worth.

Alternatively, at 812, if it is determined that the quantized first voltage signal is not greater than a noise correction threshold, the quantized second voltage signal is subtracted from the first voltage signal to alter the first voltage value. The subtraction of the digital pixel value representing the second voltage signal (e.g., the FPN signal inherent to the pixel domain) will cause the digital pixel value representing the first voltage signal (e.g., the captured light charge as well as the FPN) to more closely approximate the captured light charge without noise interference. Following the subtraction of the quantized second voltage signal from the quantized first voltage signal, the first voltage signal is then output at 814. The process 800 may then repeat again starting at 802 following another reset of the pixel domain circuit to begin processing a new pixel frame.

Some portions of this description describe the embodiments of the disclosure in terms of algorithms and symbolic representations of operations on information. These algorithmic descriptions and representations are commonly used by those skilled in the data processing arts to convey the substance of their work effectively to others skilled in the art. These operations, while described functionally, computationally, or logically, are understood to be implemented by computer programs or equivalent electrical circuits, microcode, or the like. Furthermore, it has also proven convenient at times, to refer to these arrangements of operations as modules, without loss of generality. The described operations and their associated modules may be embodied in software, firmware, and/or hardware.

Steps, operations, or processes described may be performed or implemented with one or more hardware or software modules, alone or in combination with other devices. In some embodiments, a software module is implemented with a computer program product comprising a computer-readable medium containing computer program code, which can be executed by a computer processor for performing any or all of the steps, operations, or processes described.

Embodiments of the disclosure may also relate to an apparatus for performing the operations described. The apparatus may be specially constructed for the required purposes, and/or it may include a general-purpose computing device selectively activated or reconfigured by a computer program stored in the computer. Such a computer program may be stored in a non-transitory, tangible computer-readable storage medium, or any type of media suitable for storing electronic instructions, which may be coupled to a computer system bus. Furthermore, any computing systems referred to in the specification may include a single processor or may be architectures employing multiple processor designs for increased computing capability.

Embodiments of the disclosure may also relate to a product that is produced by a computing process described herein. Such a product may include information resulting from a computing process, where the information is stored on a non-transitory, tangible computer-readable storage medium and may include any embodiment of a computer program product or other data combination described herein.

The language used in the specification has been principally selected for readability and instructional purposes, and it may not have been selected to delineate or circumscribe the inventive subject matter. It is therefore intended that the scope of the disclosure be limited not by this detailed description, but rather by any claims that issue on an application based hereon. Accordingly, the disclosure of the embodiments is intended to be illustrative, but not limiting, of the scope of the disclosure, which is set forth in the following claims.

What is claimed is:

1. A sensor apparatus comprising:
a pixel cell configured to generate a voltage, the pixel cell including one or more photodiodes configured to generate a charge in response to light and a charge storage device to convert the charge to a voltage;
an integrated circuit comprising a plurality of integrated memory circuits and configured to:
generate, based on a first voltage obtained from the charge storage device of the pixel cell, a first voltage value during a first time period; and
generate, based on a second voltage generated by fixed pattern noise from the pixel cell and the integrated circuit, a second voltage value occurring a second time period;
one or more analog-to-digital converters (ADC) configured the convert the first voltage value to a first digital pixel value and the second voltage value to a second digital pixel value; and
a processor configured to generate a third digital pixel value based on the first digital pixel value and the second digital pixel value.

2. The apparatus of claim 1, wherein the processor is further configured to:
determine a threshold pixel value;
compare the first digital pixel value to the threshold pixel value, wherein the processor is configured to generate the third digital pixel value based on the comparison.

3. The apparatus of claim 2, wherein:
comparing the first digital pixel value to the threshold pixel value comprises determining that the first digital pixel value is greater or equal to than the threshold pixel value;
the third digital pixel value is the first digital pixel value.

4. The apparatus of claim 2, wherein:
comparing the first digital pixel value to the threshold pixel value comprises determining that the first digital pixel value is less than the threshold pixel value;
the third digital pixel value is generated based on a difference between the first digital pixel value and the second digital pixel value.

5. The apparatus of claim 4, wherein generating the third digital pixel value based on a difference between the first digital pixel value and the second digital pixel value comprising subtracting a binary number representing the second digital pixel value from a binary number representing the first digital pixel value to generate a binary number representing the third digital pixel value.

6. The apparatus of claim 2, wherein the threshold pixel value is determined based the first time period and a configuration of the pixel cell.

7. The apparatus of claim 2, wherein the threshold pixel value is received from an external application executing on a computing device communicatively coupled to the sensor apparatus.

8. The apparatus of claim 1, wherein:
the first digital pixel value is stored on a first static random-access memory of the sensor apparatus;
the second digital pixel value is stored on a second static random-access memory of the sensor apparatus;
generating the third digital pixel value comprises accessing, from the first static random-access memory and the second static random-access memory, the first digital pixel value and the second digital pixel value.

9. The apparatus of claim 8, wherein the integrated circuit comprises:
a first memory switch configured to transfer the first voltage value to the first static random-access memory during the first time period;
a second memory switch configured to transfer the second voltage value to the first static random-access memory during the first time period;
a latch configured to open and close the first memory switch and the second memory switch during the first and second time periods.

10. The apparatus of claim 1, wherein the charge storage device converts the charge from the one or more photodiodes to a voltage during the first time period and does not convert the charge from the one or more photodiodes during the second time period.

11. The apparatus of claim 10, wherein the pixel cell comprises a switch to connect the charge storage device to the one or more photodiodes during the first time period and disconnect the charge storage device from the one or more photodiodes after the first time period.

12. The apparatus of claim 1, wherein:
the pixel cell further comprises an adaptive range gate;
the pixel cell is configured to generate a charge in a high-gain format when the adaptive range gate is opened and in a moderate-gain format when the adaptive range gate is closed.

13. The apparatus of claim 12, wherein:
the charge storage device is a first charge storage device;
the pixel cell further comprises a second charge storage device, the adaptive range gate connecting the one or more photodiodes to the second charge storage device;
the pixel cell is configured to generate a charge in a low-gain format when the adaptive range gate is closed to cause the second charge storage device to convert the charge from the one or more photodiodes to a voltage.

14. The apparatus of claim 1, wherein:
the charge storage device is a first charge storage device;
the integrated circuit further comprises a second charge storage device configured to convert a charge from the first charge storage device to a third voltage;
generating the second voltage value is generated based at least on the third voltage converted by the second charge storage device.

15. The apparatus of claim 1, wherein the sensor apparatus further comprises a sense amplifier configured to generate an amplified digital pixel value based on the third digital pixel value.

16. The apparatus of claim 15, wherein:
the sensor apparatus further comprises a peripheral processing system comprising the sense amplifier and the processor;
the processor is further configured to export the amplified digital pixel value to an external processing system.

17. The apparatus of claim 16, wherein:
the processor is further configured to export the first digital pixel value, the second voltage value, and the third digital pixel value to the external processing system;
the external processing system is further configured to generate, based on the first digital pixel value, the first voltage value, the second voltage value, and the third digital pixel value, a fourth digital pixel value.

18. The apparatus of claim 16, wherein the peripheral processing system is configured to:
receive one or more additional digital pixel values from one or more additional processors; and
generate digital image data using the amplified digital pixel value and the one or more additional digital pixel values.

19. The apparatus of claim 18, wherein:
the peripheral processing system is further configured to export the digital image data to an external application executing on the external processing system;
the external processing system comprises a digital display configured to display a digital image generated by the external application based on the digital image data received from the peripheral processing system.

20. A method comprising:
generating a first voltage by converting a charge of light received at one or more photodiodes;
generating, using a first memory circuit and based on the first voltage, a first voltage value during a first time period;
generating a second voltage based on a fixed pattern noise present in a circuit including the one or more photodiodes;
generating, using a second memory circuit and based on the first voltage, a second voltage value occurring a second time period;
converting the first voltage value to a first digital pixel value and the second voltage value to a second digital pixel value; and
generating an first altered digital pixel value based on the first digital pixel value and the second digital pixel value.
